(19) United States
(12) Patent Application Publication
(10) Pub. No.: US 2026/0121492 A1
(43) Pub. Date: Apr. 30, 2026

(54) MOTOR CONTROLLER POTTING SHIELD

(71) Applicant: Nidec Motor Corporation, St. Louis, MO (US)

(72) Inventors: Daniel E. Bailey, Ballwin, MO (US); Victor Hugo Dos Santos, Santa Catarina (BR); Warren Rixon, Springfield, IL (US); Jeffrey Scott Sherman, Creve Coeur, MO (US); Chetan O. Modi, Valley Park, MO (US); Steven Faust, St. Louis, MO (US)

(73) Assignee: Nidec Motor Corporation, St. Louis, MO (US)

(21) Appl. No.: 19/373,437

(22) Filed: Oct. 29, 2025

Related U.S. Application Data
(63) Continuation-in-part of application No. 18/933,584, filed on Oct. 31, 2024.

(51) Int. Cl. H02K 11/33; H02K 11/00; H02K 11/02; H05K 7/20

(52) U.S. Cl. CPC H02K 11/33; H02K 11/0094; H02K 11/02; H05K 7/209; H02K 2211/03

(57) ABSTRACT

A motor includes a controller can, a controller, and potting material encasing at least a portion of the controller. The controller includes a primary electronics board, a plurality of primary electronics components mounted to the primary electronics board, a plurality of secondary electronics components, and a potting shield. The controller can and the potting shield at least in part define a controller chamber including a primary chamber portion and a secondary chamber portion. The primary electronics components are at least substantially located in the primary chamber portion. The secondary electronics components are at least substantially located in the secondary chamber portion. The potting shield is disposed between the primary and secondary chamber portions.

### CROSS-REFERENCE TO RELATED APPLICATION

### 1. Priority Application

The present application is a continuation-in-part of U.S. patent application Ser. No. 18/933,584, filed Oct. 31, 2024, and entitled MOTOR POWER MODULE CLAMPING ARRANGEMENT, the entire disclosure of which is hereby incorporated by reference herein.

### BACKGROUND OF THE INVENTION

### 1. Field of the Invention

The present invention relates generally to a clamping and spacing assembly and method for positioning and securing a heat-generating component relative to a heatsink and an electronics board.

### 2. Discussion of the Prior Art

Electric motors conventionally include a controller including a printed circuit board and electronics components mounted thereto. Such components may include one or more switches, sensors, additional circuit boards, power modules, and more. Because controllers typically generate substantial heat, they are often positioned in the motor assembly to facilitate transfer of thermal energy. For instance, the power module of a controller might be mounted directly to a heatsink to aid in thermal management. Various mounting techniques are conventionally used to secure power modules relative to heatsinks. Power modules are also conventionally connected to associated electronics boards, such as printed circuit boards.

### SUMMARY

According to one aspect of the present invention, a motor comprises a controller can, a controller, and potting material encasing at least a portion of the controller. The controller includes a primary electronics board, a plurality of primary electronics components mounted to the primary electronics board, a plurality of secondary electronics components, and a potting shield. The controller can and the potting shield at least in part define a controller chamber including a primary chamber portion and a secondary chamber portion. The primary electronics components are at least substantially located in the primary chamber portion. The secondary electronics components are at least substantially located in the secondary chamber portion. The potting shield is disposed between the primary and secondary chamber portions.

Another aspect of the present invention concerns a method of potting a controller in a motor controller chamber. The controller includes a plurality of electronics components. The controller chamber includes a primary chamber portion and a secondary chamber portion each at least in part defined by a controller can and a potting shield disposed between the portions. The method includes the steps of: (a) supplying potting material into the primary chamber portion of the controller chamber, such that the potting material at least in part encases a first plurality of the electronics components located in the primary chamber portion; (b) supplying additional potting material into the secondary chamber portion of the controller chamber, such that the additional potting material at least in part encases a second plurality of electronics components located in the secondary chamber portion; and (c) after commencement of step (b), directing a portion of the additional potting material to flow from the secondary chamber portion into the primary chamber portion through a flow-through gap at least in part defined by the potting shield.

This summary is provided to introduce a selection of concepts in a simplified form. These concepts are further described below in the detailed description of the preferred embodiments. This summary is not intended to identify key features or essential features of the claimed subject matter, nor is it intended to be used to limit the scope of the claimed subject matter.

Various other aspects and advantages of the present invention will be apparent from the following detailed description of the preferred embodiments and the accompanying drawing figures.

### BRIEF DESCRIPTION OF THE DRAWING FIGURES

Preferred embodiments of the present invention are described in detail below with reference to the attached drawing figures, wherein:

FIG. 1 is a perspective view of a motor in accordance with a first preferred embodiment of the present invention;

FIG. 2 is an enlarged, partially fragmented exploded view of the main electronics board, daughter electronics board, power module, and spacing insert and nuts of the motor of FIG. 1;

FIG. 3 is an exploded perspective view of the daughter electronics board and the spacing insert of FIG. 2;

FIG. 4 is a partially exploded perspective view of the assembly of FIG. 3, in addition to a pair of nuts that, along with the spacing insert, form part of a clamping assembly;

FIG. 5 is a partially exploded perspective view of the assembly of FIG. 4, in addition to a heat-generating component (a power module);

FIG. 6 is a partially exploded perspective view of the assembly of FIG. 5, mounted to the main electronics board of FIGS. 1 and 2, in addition to a thermal sheet;

FIG. 7 is a partially sectioned perspective view of the assembly of FIG. 6, placed in the controller can of the motor of FIG. 1;

FIG. 8 is a partially exploded perspective view of the assembly of FIG. 7, in addition to a potting shield and a pair of bolts for fastening the power module to the heatsink of the controller can;

FIG. 9 is a partially sectioned, non-exploded perspective view of the assembly of FIG. 8, prior to tightening of the bolts;

FIG. 10 is a perspective view of the assembly of FIG. 9 after tightening of the bolts and resultant shifting of the nuts along the bolt shafts and away from the spacing insert, wherein clamping surfaces defined by the nuts and bolts clamp the power module and a portion of the heatsink therebetween;

FIG. 11 is an alternative partially sectioned perspective view of the assembly of FIG. 10, with the addition of potting material filling the potting chamber;

FIG. 12 is an enlarged perspective view of the daughter board, spacing insert, nuts, and power module of FIGS. 5-11;

FIG. 13 is a cross-sectional side view of the daughter board, spacing insert, nuts, and power module of FIG. 12, in addition to the thermal sheet and heatsink wall of the controller can, particularly illustrating key dimensions of the assembly;

FIG. 14 is an alternative perspective view of the daughter board, spacing insert, nuts, and power module (only pins thereof being visible) of FIGS. 5-13;

FIG. 15 is an enlarged rear perspective view of the spacing insert of FIGS. 2-14;

FIG. 16 is a front perspective view of the spacing insert of FIGS. 2-15;

FIG. 17 is a rear view of the spacing insert of FIGS. 2-16;

FIG. 18 is a cross-sectional side view of a daughter electronics board, spacing insert, nuts, and power module in accordance with a second preferred embodiment of the present invention;

FIG. 19 is a cross-sectional side view of the daughter board, spacing insert, nuts, and power module of FIG. 18, in addition to a thermal sheet and heatsink wall of a controller can, particularly illustrating key dimensions of the assembly;

FIG. 20 is an alternative perspective view of the daughter board, spacing insert, nuts, and power module (only pins thereof being visible) of FIGS. 18 and 19;

FIG. 21 is an enlarged rear perspective view of the spacing insert of FIGS. 18-20;

FIG. 22 is a front perspective view of the spacing insert of FIGS. 18-21;

FIG. 23 is a rear view of the spacing insert of FIGS. 18-22;

FIG. 24 is a partially sectioned perspective view of a portion of motor in accordance with a third preferred embodiment of the present invention, particularly illustrating the motor controller and the controller can;

FIG. 25 is a partially sectioned perspective view of a portion of the motor of FIG. 24, with the addition of a first quantity of potting material in the main potting chamber, and particularly illustrating the presence of an obstructed zone therein;

FIG. 26 is an alternative perspective view of the motor similar to that of FIG. 25, but with the potting shield partially sectioned to show flow of a portion of the first quantity of potting material into the secondary potting chamber;

FIG. 27 is an alternate perspective view similar to that of FIG. 26, but with the daughter board removed;

FIG. 28 is a partially sectioned perspective view of the portion of the motor of FIGS. 24-27, similar to FIG. 27 but with the addition of a portion of a second quantity of potting material which has flowed through the secondary potting chamber and into the obstructed zone;

FIG. 29 is a partially sectioned perspective view of the portion of the motor of FIGS. 24-28, similar to FIG. 28 but with the second quantity of potting material having filled both the obstructed zone and the secondary potting chamber;

FIG. 30 is a front perspective view of the potting shield of the motor of FIGS. 25-29; and

FIG. 31 is a rear perspective view of the potting shield of FIG. 30.

The drawing figures do not limit the present invention to the specific embodiments disclosed and described herein. While the drawings do not necessarily provide exact dimensions or tolerances for the illustrated structures or components, the drawings are to scale with respect to the relationships between the components of the structures illustrated in the drawings.

### DETAILED DESCRIPTION

The present invention is susceptible of embodiment in many different forms. While the drawings illustrate, and the specification describes, certain preferred embodiments of the invention, it is to be understood that such disclosure is by way of example only. There is no intent to limit the principles of the present invention to the particular disclosed embodiments.

Furthermore, unless specified or made clear, the directional references made herein with regard to the present invention and/or associated components (such as top, bottom, upper, lower, inner, outer, and so on.) are used solely for the sake of convenience and should be understood only in relation to each other. For instance, a component might in practice be oriented such that faces referred to as “top” and “bottom” are sideways, angled, inverted, and so on. relative to the chosen frame of reference.

### Motor Overview

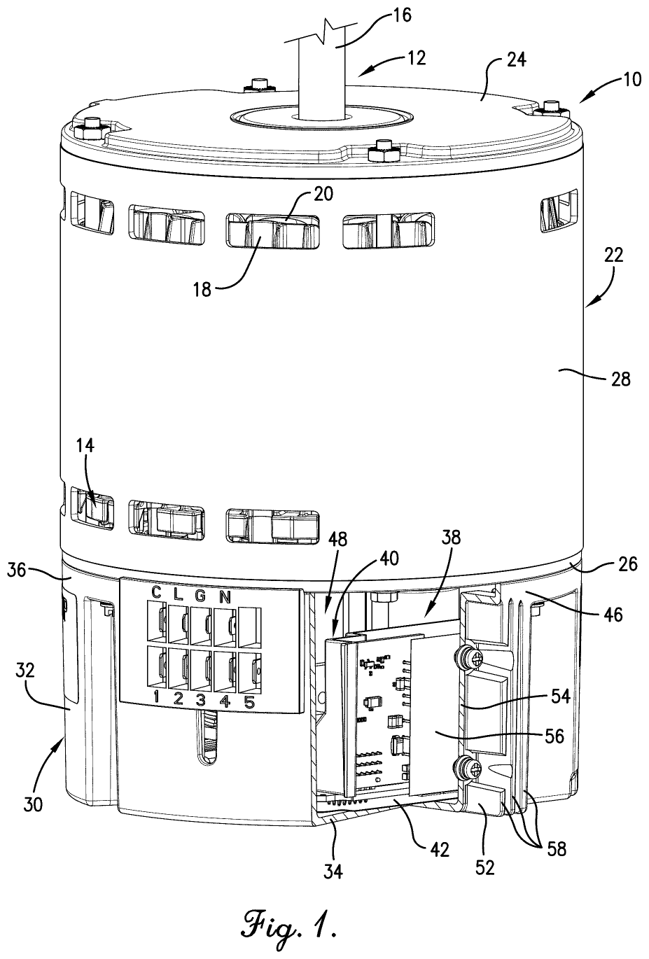

With initial reference to FIG. 1, an electric motor 10 is provided for use in a machine or system. Any of a variety of machines or systems are suitable, including but not limited to residential air moving equipment.

The motor 10 broadly includes a rotor 12 and a stator 14. The rotor 12 is rotatable about an axis. In a preferred embodiment, as shown, the stator 14 at least substantially circumscribes the rotor 12, such that the motor 10 is an inner rotor motor.

The rotor 12 preferably includes a rotor core (not shown), a plurality of magnets (not shown), and a shaft 16 defining a rotational axis for the rotor 12. The stator 14 preferably includes a stator core (not shown), an electrically insulative covering 18 on the stator core, and a plurality of coils 20 wound about the stator core. Other stator and rotor configurations fall within the scope of some aspects of the present invention, however.

The motor 10 preferably further includes a motor housing 22 including a pair of spaced apart first and second endshields 24 and 26, a shell 28 extending between and interconnecting the endshields 24 and 26, and a controller can 30 mounted to the second endshield 26.

The controller can 30 preferably includes a can housing 32 including a generally radially extending end plate 34 spaced from the endshield 26 and a generally circumferential skirt 36 extending at least substantially axially from the end plate 34 toward the shell 28. The skirt 36 most preferably extends toward and into engagement with the endshield 26.

The can housing 32 and the endshield 26 preferably cooperatively define a controller chamber 38. The motor 10 preferably includes a controller 40 at least in part and most preferably at least substantially received in the controller chamber 38.

The controller 40 preferably includes a main, primary, or parent motor board or electronics board 42 and a plurality of electronics components 44 mounted on the electronics board 42. Most preferably, the electronics board 42 is a printed circuit board (PCB).

The electronics components 44 may include one or more primary control and/or pilot control devices, such as power modules (discussed in more detail below), motor starters, float switches, pressure switches, magnetic contactors, contactor coils, circuit breakers, overload relays, and/or other components enabling or facilitating motor operation and/or control.

As will be discussed in greater detail below, one or more additional or daughter electronics or motor boards may also be mounted to the main or primary PCB 42. In a broad sense, any of a variety of controller types, configurations and components are permissible according to some aspects of the present invention.

In a preferred embodiment, as illustrated in FIG. 1, the main PCB 42 is generally planar and overlies or nearly overlies the end plate 34 of the can housing 32. The electronics components 44 extend from the PCB 42 into the controller chamber 38 and toward the second endshield 36. Inverted configurations fall within the scope of some aspects of the present invention, however, as do entirely different configurations.

The can 30 further preferably includes a thermal insert 46 received in an arcuate gap 48 defined by the skirt 36. In a preferred embodiment, as illustrated, the thermal insert 46 is a discrete component, although integral formation with the rest of the can housing is permissible according to some aspects of the present invention.

The thermal insert 46 is preferably exposed to the exterior of the can 30 and constitutes at least part of a heatsink 52. That is, the thermal insert 46 (and, more broadly, the heatsink 52) acts to absorb and redirect heat in order to support efficient, rapid heat transfer from the controller 40, chamber 38, and can 30 to an external space. It is noted that other portions of the can housing 32 or can 30 in general may also act as heatsinks.

More particularly, the thermal insert 46 (or, alternatively stated, the motor can 30) preferably includes a wall 54 for absorbing heat from the controller 40. A pair of openings 55 are formed through the wall 54 and will be discussed in greater detail below.

In the illustrated embodiment, the heatsink 52 further includes a thermal transfer sheet 56 that overlies the wall 54 and provides additional thermal conductivity. A pair of openings 57 are formed through the thermal sheet 56 and will also be discussed in greater detail below.

The thermal insert 46 preferably defines a plurality of heat transfer fins 58. The fins 58 are configured to disperse heat from the controller 40, compartment or chamber 38, and can 30.

The material of the can housing 32 may be selected from a group of materials having relatively low heat conductivity. More particularly, each such material may be selected for its ability to remain at or below a certain temperature during operation of motor 10, thereby preventing heat damage that may otherwise be caused by proximity of the can housing 32 (for example, an inner surface of the end plate 34 thereof) to the controller 40. Preferably, the can housing 32 comprises a synthetic resin. More specifically, the can housing 32 preferably comprises a polycarbonate.

In contrast, the material of the thermal insert 46 or heatsink 52 is preferably selected from a group of materials having relatively high thermal conductivity. More particularly, each such material is preferably selected for its ability to transfer heat efficiently and quickly from the controller 40 and the associated chamber 38 to the external space. The thermal insert 46 and thermal sheet 56 may preferably comprise metal, for instance, such as steel or aluminum.

Interconnection of the controller 40 to the insert 46 or heatsink 52 will be described in greater detail below. In a broad sense, however, one or more of the electronics components 44 is preferably thermally connected to (that is, is in thermal communication with) the heatsink 52. That is, the at least one of the electronics components 44 transfers thermal energy to the heatsink 52 directly through conductive contact and/or indirectly via conductive contact with one or more intermediaries having relatively favorable heat transfer properties and dimensions for heat transfer. More preferably, the heat transfer properties of any such intermediary are at least as conducive to heat transfer as the material(s) comprising the heatsink 52 and are dimensioned so as to provide for efficient heat transfer to the heatsink 52. Most preferably, however, the component 44 transfers heat through direct contact with the heatsink 52.

### Controller Components

In a preferred embodiment of the present invention, the electronics components 44 of the controller 40 include a power module 60 and a daughter electronics board 62, in addition to other components. Selected ones of these components will be described in greater detail below.

### Daughter Board

The daughter board 62 is preferably a secondary printed circuit board (PCB) to which its own electronics components 64 are mounted. The daughter board 62 is preferably mounted to the main electronics board 42. Most preferably, the daughter board 62 is mounted generally orthogonally to the main PCB 42.

More particularly, the daughter board 62 preferably includes a board body 66 and a plurality of connector pins 68 mounted to the board body 66. The pins 68 are provided in four (4) sets 68a, 68b, 68c, and 68d and are generally L-shaped in form. A first end of each pin 68 extends through and is connected to the daughter board 62, and a second end of each pin 68 extends through and is connected to the main PCB 42. Such connections may be via soldering or another process having a suitable effect.

The body 66 of the daughter board 62 preferably includes two (2) side sections 70 and 72 interconnected by a central bridge 74. The side sections 70 and 72 are preferably substantially similarly sized and shaped to one another, although size and shape variations fall within the scope of some aspects of the present invention. In the illustrated embodiment, for instance, the side section 72 is generally wider than the section 70 and is not entirely rectangular in form.

The bridge 74 preferably presents a smaller area than the side sections 70 and 72, although other relative sizing is permissible. Preferably, the side sections 70 and 72 each have a width that is larger than the width of the bridge 74. The side sections 70 and 72 also preferably present a height that is greater than the height of the bridge 74. The bridge 74 is preferably at least substantially centered along the height of the side sections 70 and 72, although offset configurations are permissible.

In a preferred embodiment, the daughter board body 66 defines a plurality of pin-receiving openings 76. More particularly, a first set of pin-receiving openings 76a extends through the first side section 70 of the daughter board 62. Second and third sets of pin-receiving openings 76b and 76c extend through the second side section 72. The configuration of the pin-receiving openings 76a, 76b, and 76c preferably corresponds to the pin configuration details of the associated power module 60, which will be discussed in greater detail below.

### Power Module

The power module 60 preferably includes a body 78 including a broad and preferably substantially planar outward-facing or heatsink-facing surface 80. The surface 80 preferably sits adjacent and substantially parallel to the thermal sheet 56 and the wall 54 of the thermal insert 46 in the assembled motor 10. More particularly, the heatsink-facing surface 80 preferably physically engages the thermal sheet 56, such that the thermal sheet 56 absorbs heat from the power module 60 and distributes the heat across a broader surface area along the interface with the wall 54 of the thermal insert 46.

The power module body 78 further preferably includes a broad and substantially planar inward-facing surface or board-facing surface 82 opposed to the heatsink-facing surface 80.

A plurality of pins 84 extend from the power module body 78. More particularly, a first sets of pins 84a extends from one side of the body 78 and second and third sets of pins 84b and 84c extend from the other side of the body 78. The pins 84a, 84b, and 84c preferably correspond with the three (3) sets of pin-receiving openings 76a, 76b, and 76c in the daughter board 62 and are received therein during assembly of the controller 40.

The power module 60 also preferably includes two (2) notches 86 and 88 disposed at opposed top and bottom ends thereof. The notches 86 and 88 each preferably extend through the body 78 from the heatsink-facing surface 80 to the board-facing surface 82. The notches 86 and 88 will be discussed in greater detail below.

It is noted that, according to some aspects of the present invention, the power module 60 could instead be any heat-generating component. That is, while a power module 60 is an exemplary and frequently utilized heat-generating component of an electric motor, other heat-generating components may be provided in association with some aspects of the present invention.

### Clamping Assembly

The motor 10 additionally preferably includes a clamping assembly 90. The clamping assembly 90 broadly includes a spacing or positioning insert or element 92 and a pair of fixation elements 94. The spacing insert 92 is mounted to the daughter board 62 and at least in part disposed between the daughter board 62 and the heat-generating component 60. As will be described in detail below, the clamping assembly 90 secures the heat-generating component 60 (such as the power module 60) relative to the daughter electronics board 62 and the heatsink 52 of the controller can 30.

More particularly, the daughter board 62 presents a front or outer board surface 96 that faces both the heatsink 52 and the power module or heat-generating component 60. When the daughter board 62 is mounted to the main PCB 42 and the controller 40 is mounted in the can 30, the board surface 96 is spaced from the heatsink 52 by a gap distance D (see FIG. 13). The clamping assembly 90 positions and secures the heat-generating component or power module 60 relative to the daughter board or electronics board 60 and the heatsink 52 such that a distance between the daughter board surface 96 and the heatsink-facing component or power module surface 80 is substantially equal to the gap distance D, and such that the heat-generating component 60 is secured in thermal communication with the heatsink 52.

As noted previously, the clamping assembly 90 in a preferred embodiment of the present invention includes the spacing insert or positioner 92 and the pair of fixation elements 94. The spacing insert 92 preferably includes an insert body 98 having front or power module-facing and back or daughter board-facing sides 100 and 102. The spacing insert 92 further preferably includes a plurality of projections 104 extending from the front side 100 of the insert body 98.

The insert body 98 is preferably spaced from the power module or heat-generating component body 78. However, the projections 104 preferably extend from the insert body 98 and engage the power module body 78.

Adjacent ones of the projections 104 preferably define flow-through gaps 106 therebetween. As will be discussed in greater detail below, the flow-through gaps 106 facilitate flow of potting material 108 therethrough such that the potting material 108 more fully engages the power module 60.

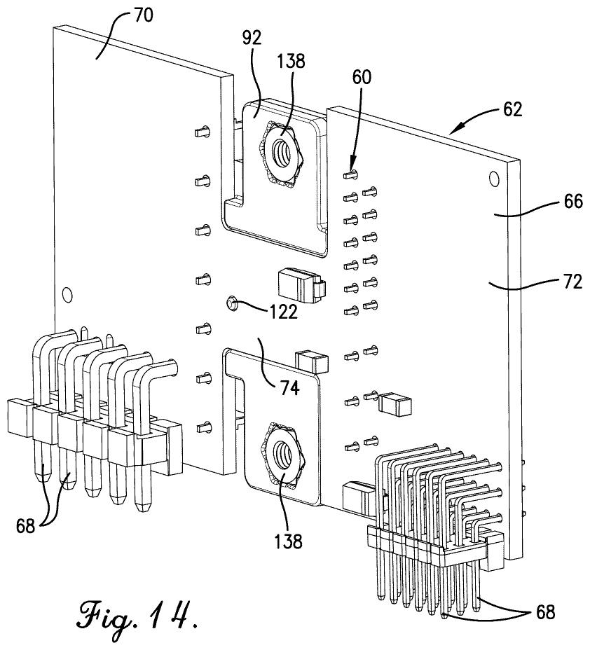

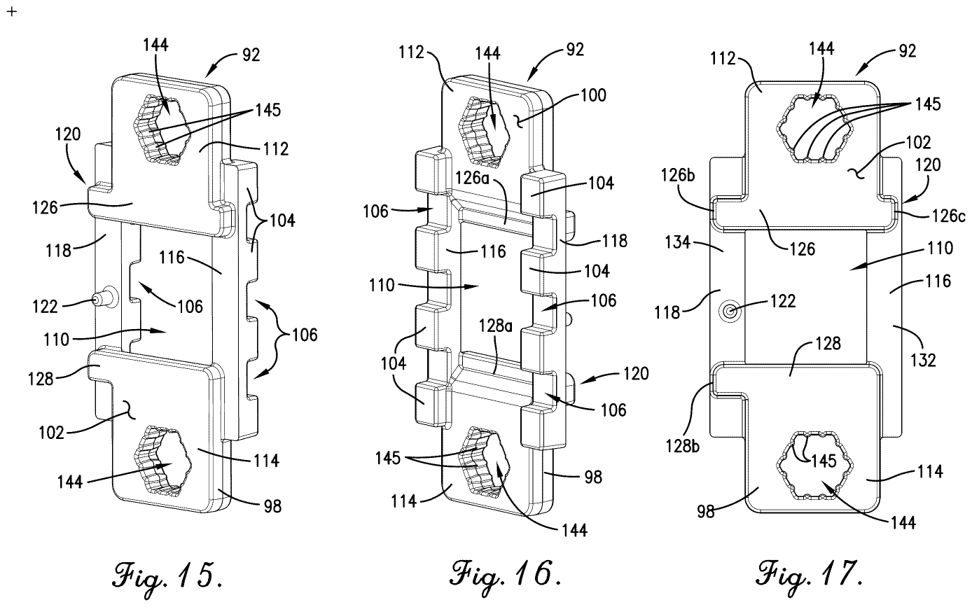

As best shown in FIGS. 15-17, the insert body 98 preferably defines a central aperture 110 such that the body 98 may be understood to include top and bottom sections 112 and 114 and side rails 116 and 118 extending between and interconnecting the top and bottom sections 112 and 114.

The projections 104 preferably extend from respective ones of the side rails 116 and 118. In the illustrated embodiment, for instance, four (4) evenly spaced apart and congruent projections 104 extend from each of the side rails 116 and 118. However, other configurations facilitating flow-through of potting material are permissible according to some aspects of the present invention. For instance, uneven spacing is permissible, as is irregular sizing and shaping of the projections.

It is also permissible according to some aspects of the present invention for projections to be omitted entirely, with the body of the spacing insert instead directly engaging the heat-generating component.

The spacing insert 92 further preferably includes a plurality of positioning elements 120 extending from the body 98. For instance, a positioning peg 122 preferably extends from the side rail 116, in a direction opposite that of the projections 104 (that is, from the back side 102 of the body 98), and is received in a corresponding peg opening 124 defined by the bridge 74 of the daughter board 62.

Furthermore, top and bottom bumpers 126 and 128 extend inwardly and sideways from the top and bottom sections 112 and 114 of the insert body 98 to in part define the aforementioned central aperture 110. Each bumper 126 and 128 includes a respective stepped or tiered portion 126a or 128a, part of each of which is configured to abut the corresponding top or bottom edge of the bridge 74 of the daughter board 62 when the spacing insert 92 is mounted thereto.

The top bumper 126 preferably also extends laterally past both sides of the top section 112 to define a pair of laterally opposed side faces 126b and 126c that engage respective ones of the daughter board sections 70 and 72. The bottom bumper 128, in contrast, extends laterally past only one side of the bottom section 112 to define a single side face 128b that engages the daughter board section 72.

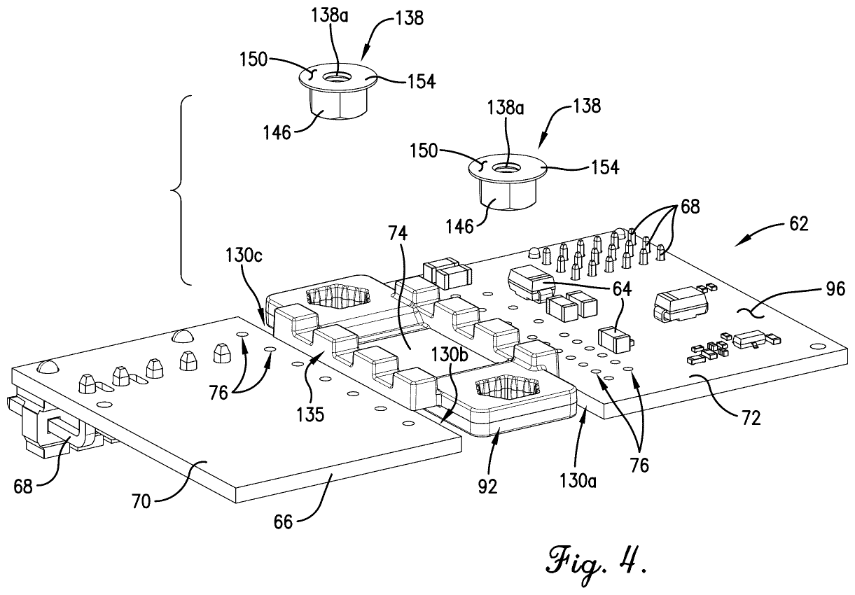

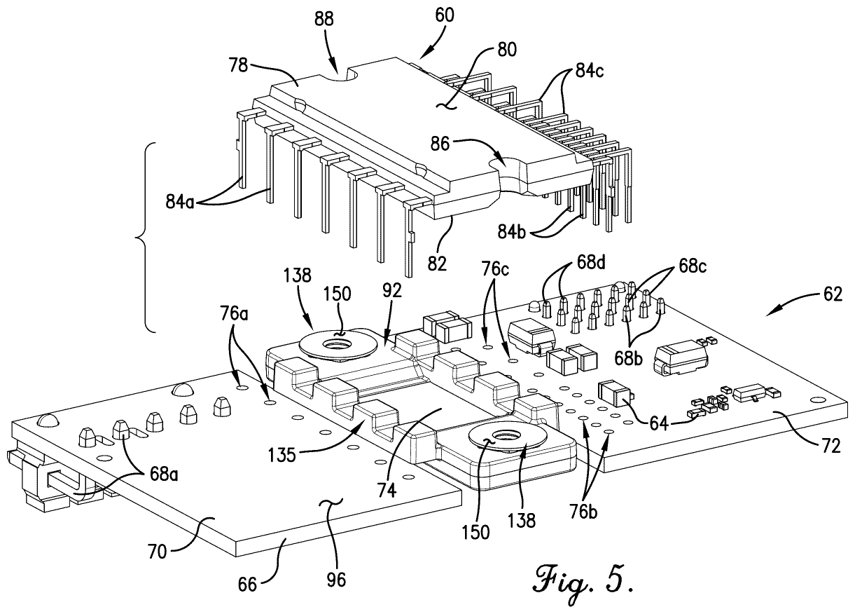

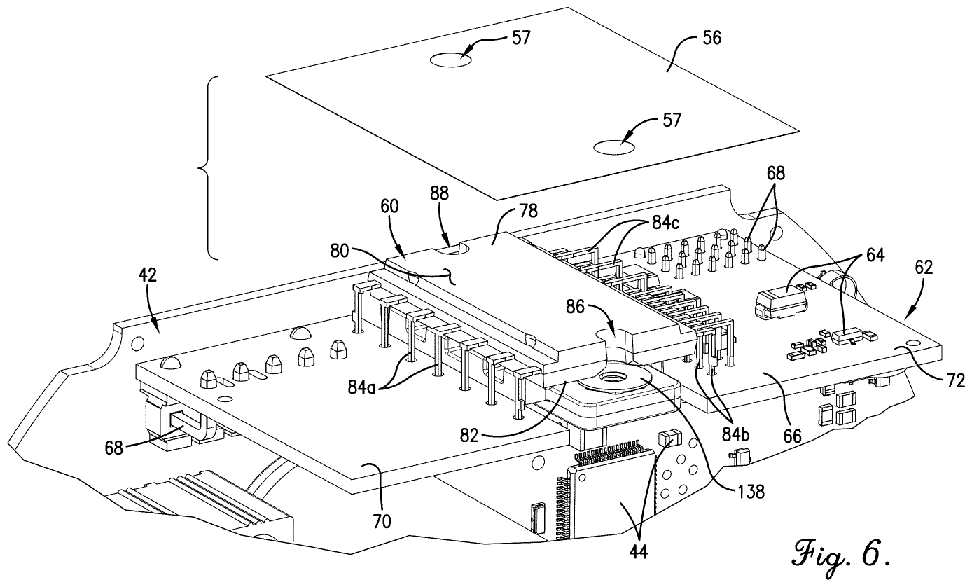

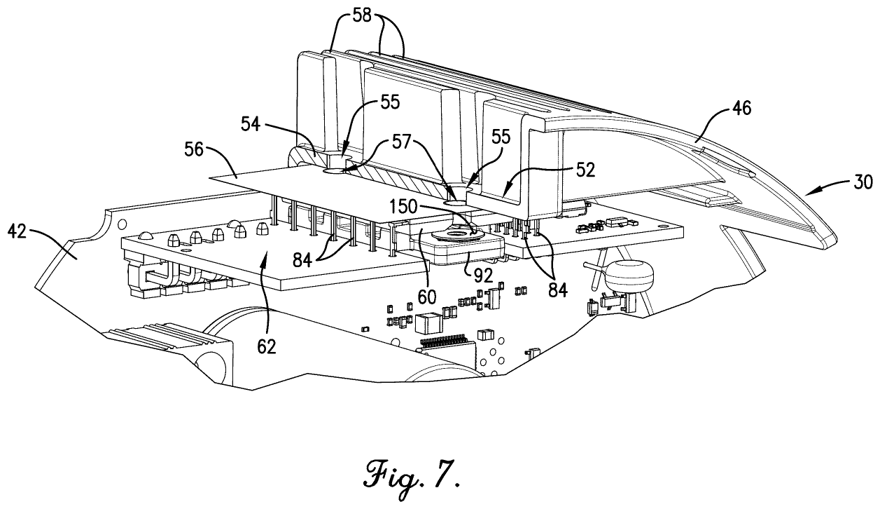

The shapes of the daughter board sections 70 and 72, in combination with the shape of the spacing insert 92, including the bumpers 126 and 128, is such that gaps 130a, 130b, and 130c (see, for instance, FIG. 4) are defined therebetween.

Each side rail 116 and 118 defines a back side corresponding to the back side 102 of the insert body 98. An overhanging portion 132 or 134 (see FIG. 17), respectively, of the back side of each side rail 116 and 118 preferably overlies corresponding portions of the sections 70 and 72 and/or the bridge 74 of the daughter board 62. Alternatively stated, the overhanging portions 132 and 134 overlie a portion of the front daughter board surface 96.

Thus, as will be apparent to those of ordinary skill in the art, the overhanging portions 132 and 134, the positioning peg 122, and the bumpers 126 and 128 cooperatively position the spacing insert 92 relative to both the daughter board 62 and the power module 60.

The positioning of the spacing insert 92 is preferably such that a spacer portion 135 thereof is disposed outward or forward (that is, toward the heatsink 52) of the daughter board 62. In the illustrated embodiment, the spacer portion 135 includes the spacing insert body 98 and the projections 104.

It is noted that various alternative positioning means for the spacing insert relative to the daughter board fall within the scope of some aspects of the present invention, although such means should facilitate ease of placement and secure, stable positioning. Some variations in positioning features of the spacing insert as related to the power module are also permissible according to some aspects of the present invention, although simplicity, consistency, and compatibility with potting material flow-through are preferred qualities.

The spacing insert 92 preferably comprises a synthetic resin material. However, other materials fall within the scope of some aspects of the present invention. In a broad sense, however, it is most preferred that the spacing insert comprise a material having substantial electrically and thermally insulative properties. The material should also maintain its structure (that is, be generally rigid, non-compressible, and non-deformable) at temperatures associated with assembly of the motor 10. However, it is noted that creep and/or other forms of deformation at temperatures associated with motor operation may be expected for some materials that are considered acceptable.

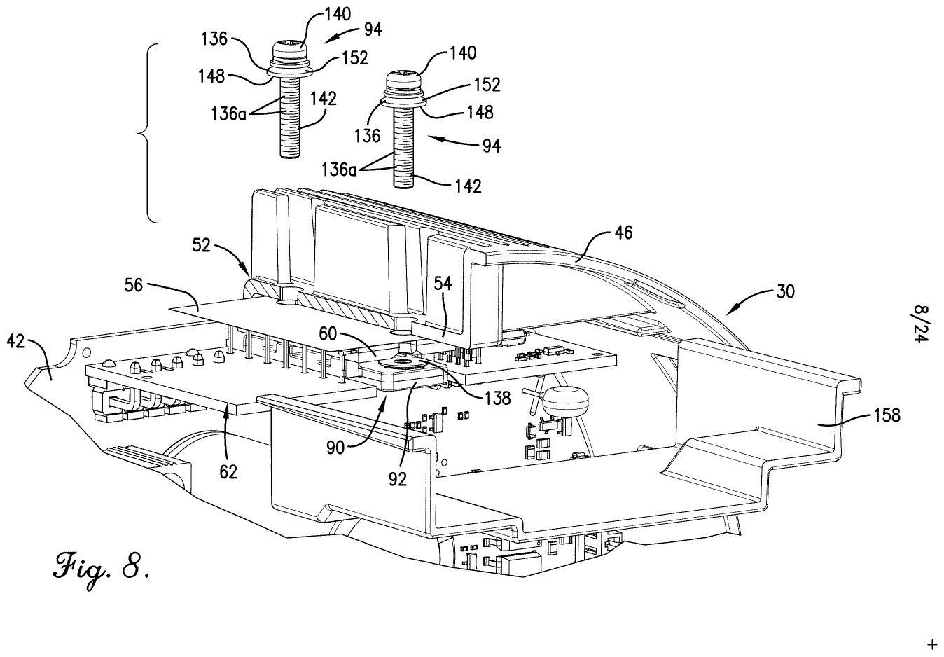

The fixation elements 94 are preferably in the form of fasteners 94. Each fastener 94 preferably includes a bolt 136 and a nut 138. The bolt 136 preferably includes a head 140 and a shaft 142 (see FIG. 8). The nut 138 is preferably shiftable along the shaft 142 toward and away from the head 140. In the illustrated embodiment, for instance, the nut 138 and the shaft 142 are provided with complementary threads facilitating such relative linear movement when the nut and shaft are rotated relative to one another. More particularly, the nut 138 is provided with internal threads 138a (FIG. 4), whereas the bolt 136 is provided with external threads 136a (FIG. 8).

As best shown in FIGS. 15-17, the insert body 98 preferably defines a pair of nut-receiving openings 144, each corresponding to one of the nuts 138. (In a broad sense, these openings may be understood to be fastener-receiving or fixation element-receiving openings 144.) More particularly, each of the top and bottom sections 112 and 114 preferably defines a respective nut-receiving opening 144.

The nut-receiving openings 144 are sized and shaped to be complementary in form to the respective nuts 138. For instance, in the illustrated embodiment, the nuts 138 include hexagonal bodies 146 (FIG. 4) that correspond to the hexagonal shape of each nut-receiving opening 144. Other shapes are permissible according to some aspects of the present invention, however, and the shapes do not necessarily have to be complementary between pairs. That is, one nut-receiving opening might be configured to receive only one of the nuts, with the other opening having a different shape and/or size to match a differently shaped and/or sized second nut.

Preferably, each nut-receiving opening 144 is at least in part defined by a plurality of radially projecting ribs 145. The ribs 145 preferably induce an interference fit of the nuts 138 in the corresponding openings 144, although other fit types fall within the scope of some aspects of the present invention.

As will be discussed in greater detail below, the ribs 145 preferably prevent rotation of the nuts 138 when the nuts 128 are subjected to forces associated with rotation or turning of the corresponding bolts 136.

In a preferred embodiment, each fastener 94 defines a pair of opposed clamping surfaces 148 and 150. More particularly, the head 140 of each bolt 136 preferably includes a flange 152 (FIG. 8) defining the clamping surface 148. Each nut 138 preferably includes a flange 154 (FIG. 4) defining the clamping surface 150.

In the assembled motor 10, the clamping surfaces 148 and 150 clamp the heat-generating component or power module 60 and the wall 54 of the heatsink 52 therebetween. More particularly, each fastener 94 extends through the openings 55 in the wall 54 and the openings 57 in the thermal sheet 56 (that is, through the heatsink 52), through the corresponding notches 86 and 88 in the power module 60, and into and through the nuts 138 received in the nut-receiving openings 144 of the spacing insert 92.

Although a pair of fasteners 94 are most preferred, more or fewer fixation elements may be provided. Furthermore, one or more such fixation elements may be in an alternative form according to some aspects of the present invention. For instance, the fixation element(s) might include elastic or springlike elements, a retention bar, latches, or other elements configured to securely retain the heat-generating component against the heatsink.

### Potting Shield

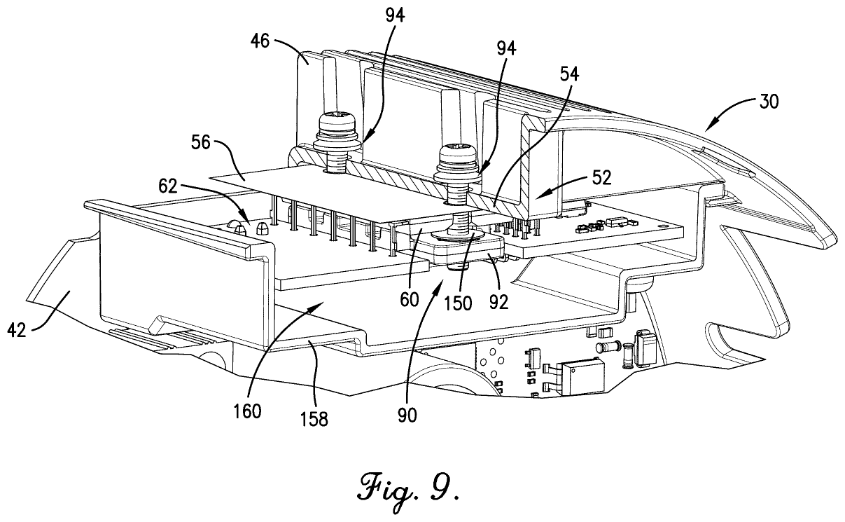

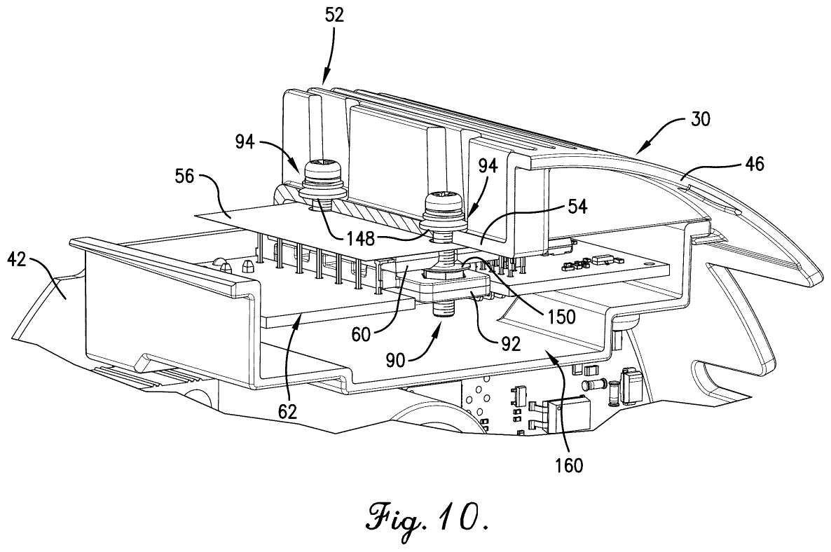

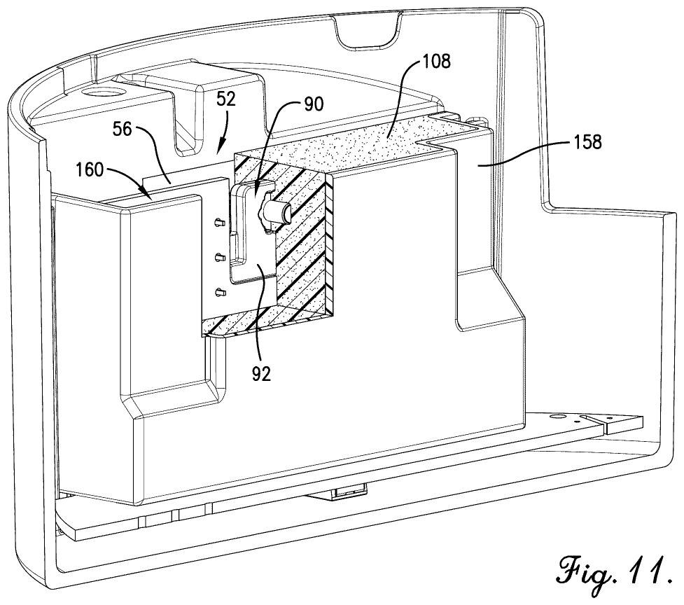

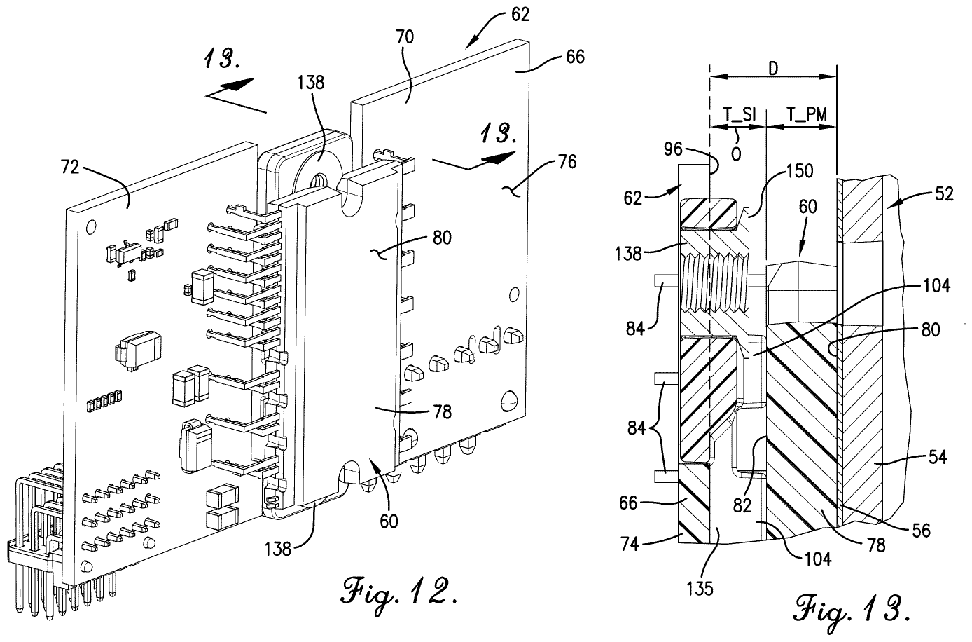

In a preferred embodiment of the present invention, the controller 40 additionally includes a potting shield 158 (see, for instance, FIGS. 9-11) that is positioned relative to the daughter board 62, the power module, the spacing insert 92 and fasteners 94, and the heatsink wall 54 to define a potting chamber 160.

More particularly, the potting shield 158 preferably includes a main body 162 and a pair of mounting flanges 164. The main body 162 preferably includes a front 166 and a pair of sides 168. The front 166 preferably includes a center section 170, a first upper side section 172, a first lower side section 174, a second upper side section 176, and a second lower side section 178.

The center section 170 is preferably rectangular in form and at least substantially centered relative to the potting shield 158 as a whole. Furthermore, in the assembled controller 40, the center section 170 is preferably generally centered relative to the daughter board 62, the power module, and the spacing insert 92 and fasteners 94.

The first and second lower side sections 174 and 178 are preferably formed continuously with and co-planar with the center section 170. In contrast, the first and second upper side sections 172 and 176 are preferably offset from the center section 170 and the lower side sections 174 and 178. More particularly, the upper side sections 172 and 176 are preferably inset, or shifted toward the daughter board 62 and so on, relative to the sections 170, 174, and 178. First and second slanted transition portions 180 and 182 preferably extend between and interconnect respective first upper and lower side sections 172 and 174 and second upper and lower side sections 176 and 178.

The configuration of the various sections of the main body 162 is preferably such that the shield 158 is spaced from the daughter board 62, the components 64 mounted thereon, and the spacing insert 92. Such spacing enables flow of potting material 108 into the potting chamber 160 (that is, between the shield 158 and the daughter board 62, the components 64 mounted thereon, and the spacing insert 92) and ensures that the potting material 108 achieves a desirable thickness.

In the illustrated embodiment, it is noted that the “bump-out” defined by the first lower side section 174 accommodates the correspondingly outwardly projecting pins 68a of the daughter board 62. Similarly, the larger “bump-out” defined by the second lower side section 178 accommodates the corresponding outwardly projecting sets of pins 68b, 68c, and 68d of the daughter board 62.

It is noted that, although the illustrated design of the main body 162 is configured to correspond specifically to the illustrated daughter board 62, power module 60, and clamping assembly 90, the potting shield may be alternately configured to correspond to changes in the design of the daughter board, power module, clamping assembly, or other relevant components.

Alternatively, use of a generically designed potting shield (for instance, one including only a single-section front and configured to accommodate various daughter board, power module, and/or clamping assembly designs, and so on) falls within the scope of some aspects of the present invention.

The sides 168 preferably extend from the front 166 toward the controller can 30. Preferably, the sides 168 extend at least substantially perpendicular to the front 166. However, oblique angles are permissible according to some aspects of the present invention.

In a preferred embodiment, as illustrated, the flanges 164 extend laterally outwardly from corresponding ones of the sides 168. Most preferably, the flanges 164 are disposed opposite the front 166, with each side 168 extending between and interconnecting a corresponding one of the flanges 164 to the front 166.

Still further, the flanges 164 in the illustrated embodiment extend at least substantially parallel to the front 168. Non-parallel configurations fall within the scope of some aspects of the present invention, however.

The flanges 164 are preferably tapered from top to bottom. More particularly, the potting shield 158 includes top and bottom edges 158a and 158b, respectively, that are cooperatively defined by the main body 162 and the flanges 164. The flanges 164 preferably have a thickness in a direction parallel to the sides 168 and are thicker at the top edge 158a than at the bottom edge 158b. That is, the flanges 164 are preferably wedge-shaped.

In even greater detail, each flange 164 preferably includes a heatsink-facing face 164a and a controller chamber-facing face 164b opposite the heatsink-facing face 164a. The face 164a is preferably orthogonal to the main PCB 42 and parallel to the front 166 and the heatsink wall 54. In contrast, the face 164b is slanted so as to form a wedge angle with the face 164a and so as to be obliquely oriented to various other parts of the controller 40 and controller can 30, such as the heatsink wall 54.

In a preferred embodiment of the present invention, each flange 164 is configured to be received in a slot or groove 184 formed by the controller can 30. More particularly, the can 30 defines a pair of guides 186 adjacent opposed ends of the daughter board 62. The guides 186 each extend inwardly from the controller can 30 and generally parallel to the heatsink wall 54 to define the respective slots 184 therebetween.

In greater detail, the guides 186 are preferably each tapered in an opposite direction to the tapering of the flanges 164. That is, the guides 186 are thinner at the tops thereof and wider at the bottoms thereof.

More particularly, as best shown in FIG. 8, each guide 186 includes a heatsink-facing face 186a and a controller chamber-facing face 186b opposite the heatsink-facing face 186a. In an opposite configuration to that of the flanges 164, the controller chamber-facing face 186b is preferably parallel to the heatsink wall 54 and orthogonal to the main PCB 42. In contrast, the heatsink-facing face 186a is slanted so as to form a wedge angle with the face 186b and so as to be obliquely oriented to various other parts of the controller 40 and controller can 30, including the heatsink wall 54.

Each slot 184 is thus also wedge-shaped, formed between the parallel/orthogonally disposed surface of the heatsink wall 54 and the slanted face 186a of the corresponding guide 186.

Most preferably, each wedge-shaped slot 184 is sized and shaped to complement the side and shape of the corresponding wedge-shaped flange 164. Thus, when the potting shield 158 is mounted to the controller can 30, the flanges 164 are securely received in corresponding ones of the slots 184.

Most preferably, fitment of the flanges 164 within the slots 184 is such that the interface therebetween is sealed against egress of potting material 108 therepast. Furthermore, the bottom edge 158b of the shield 158 preferably engages the main PCB 42 such that egress of potting material 108 therepast is also at least substantially restricted. (The potting material 108 will itself preferably form a seal along the relevant interfaces upon curing, as well.)

In a preferred embodiment of the present invention, the potting shield 158 comprises a synthetic resin material (such as a plastic). Such material is lightweight, thermally and electrically insulative, and easy to form (by molding, for instance) into the preferred configuration.

However, in some embodiments, a metal potting shield might be used instead, with the potting shield having reduced EMI potential.

It is noted that the illustrated potting shield 158 does not include a top or cover portion. However, it is permissible according to some aspects of the present invention for one or more top sections to be provided. For instance, a pair of tabs could extend from the top edge of the front toward the heatsink wall and rest thereon.

Furthermore, a closed bottom could be provided instead of the illustrated open configuration. In general, however, it is preferred that the potting chamber encompass delicate elements that benefit from the protective properties of potting. Such elements include but are not necessarily limited to the pins connecting the daughter board to the main PCB. Extension of the potting material all the way to the surface of the main PCB is thus generally desirable, at least in key locations.

Additional or alternative means of interconnection could also fall within the scope of some aspects of the present invention. For instance, the shield could be fitted into recesses or notches formed in the can wall, the heatsink wall, and/or the main PCB itself. Fasteners could also be used, including but not limited to latches, hooks, bolts and nuts, screws, and more. Adhesive-based securement methods also fall within the scope of some aspects of the present invention.

### Mounting of Power Module and Daughter Board

In a preferred method of assembling the motor 10, and, more particularly, the controller 40, the spacing insert 92 is first placed on the daughter board 62 such that the positioning peg 122 is received in the peg-receiving opening 124, the bumpers 126 and 128 abut top and bottom edges of the bridge 74 and the side faces of the first and second sections 70 and 72, and the overhanging portions 132 and 134 of the side rails 116 and 118 overlie the corresponding portions of the first and second sections 70 and 72 of the daughter board 62.

The nuts 138 are then inserted into the nut-receiving openings 144.

When the spacing insert 92 and the nuts 138 are in place, the power module or heat-generating component 60 is mounted to the daughter board 62. More particularly, the pins 84a, 84b, and 84c are received in corresponding ones of the pin-receiving openings 76a, 76b, and 76c; and the power module 60 is shifted toward the daughter board 62 until the projections 104 of the spacing insert 92 engage the board-facing surface 82 of the power module 60. The pins 84a, 84b, and 84c are then secured to the daughter board 62 by soldering or another process, with the spacing insert 92 ensuring appropriate spacing between the daughter board 62 and the power module 60 is maintained.

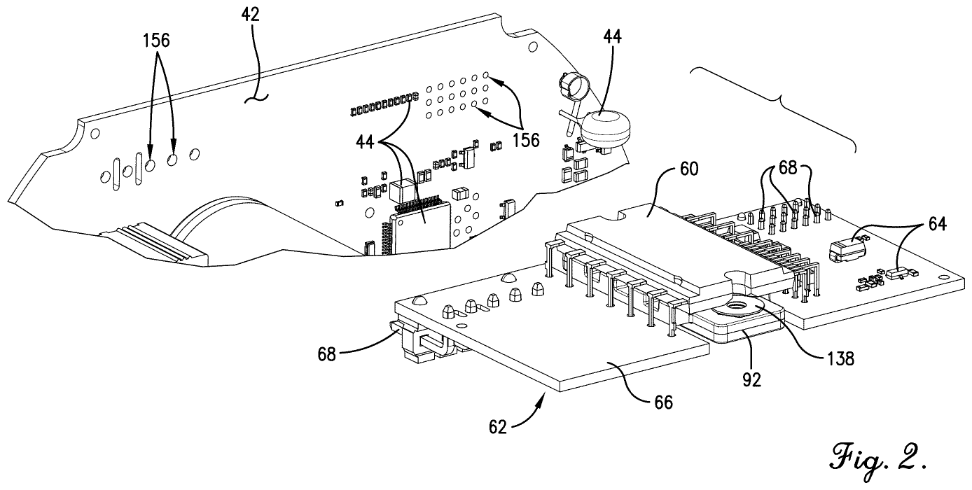

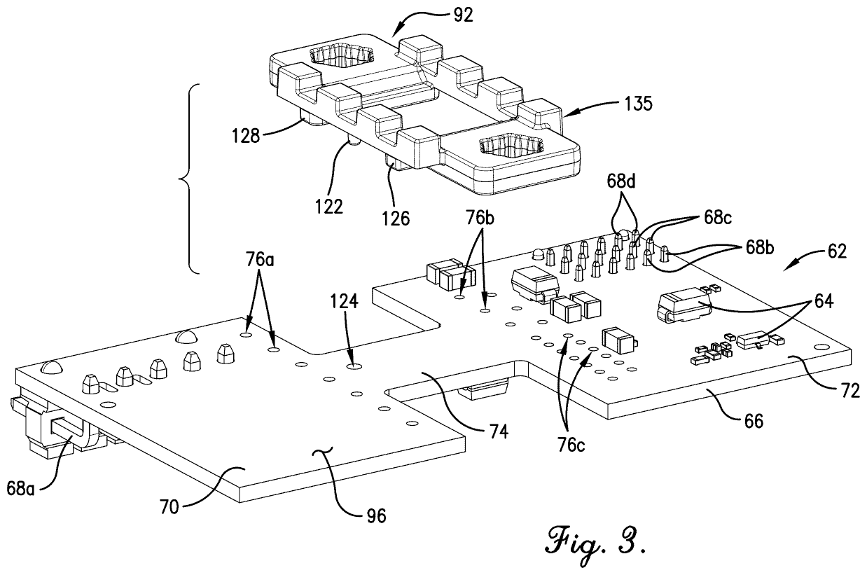

The daughter board 62 is then preferably soldered to the main PCB 42 after receipt of the daughter board pins 68a, 68b, 68c, and 68d in pin-receiving openings 156 (see FIG. 2) that are formed in the PCB 42.

The thermal sheet 56 is placed over the heatsink-facing surface 80 of the power module 60, and the thermal insert 46 is placed relative to the existing assembly such that the thermal insert 46 is aligned with and engages the thermal sheet 56.

A first one of the fasteners 94 is inserted through the corresponding openings and notches 55, 57, and 86 in the wall 54, the thermal sheet 56, and the power module 60, respectively, and thereafter into one of the nuts 138, respectively. Similarly, a second one of the fasteners 94 is inserted through the corresponding openings and notches 55, 57, and 88 in the wall 54, the thermal sheet 56, and the power module 60, respectively, and thereafter into the other of the nuts 138.

The potting shield 158 is thereafter positioned around the daughter board 62 and other components to define the potting chamber 160. More particularly, the flanges 164 of the potting shield 158 are inserted into and received within the slots 184 defined between the heatsink wall 54 and the respective guides 186.

The fasteners 94 are then rotated or turned, drawing the nuts 138 linearly along the corresponding shafts 142 and away from (and perhaps but most preferably not fully out of) the nut-receiving openings 144 defined by the spacing insert 92. It is noted that the linear drawing-up of the nuts 138 is facilitated by the ribs 145, which prevent the nuts 138 from rotating instead.

Turning of the fasteners 94 preferably continues until the clamping surfaces 150 engage the board-facing surface 82 of the power module 60 and the clamping surfaces 148 engage the wall 54 of the heatsink 52 or, more specifically, of the thermal insert 46. The power module 60 is thus clamped to the heatsink 52 by and between the clamping surfaces 148 and 150.

It is noted that, in the illustrated embodiment, the front or outer board surface 96 of the daughter board 62, the contact surface cooperatively defined by the projections 104 of the insert 92, the board-facing surface 82 and the heatsink-facing surface 80 of the power module 60, and the thermal sheet 56 and wall 54 of the heatsink 52 all extend at least substantially planarly. With the exception of the discontinuous contact surface defined by the projections 104, such surfaces all also extend at least substantially continuously. However, it is permissible according to some aspects of the present invention for surfaces to instead be angled, non-planar (for instance, with surface features), and/or discontinuous. It is nevertheless important in such alternative embodiments that the surface of one component engages the surface of the other component. That is, at least some degree of complementarity between adjacent surfaces is desirable to support engagement therebetween.

Potting material 108 may then be injected or otherwise introduced into the potting chamber 160, flowing thorough the flow-through gaps 106 between the projections 104 of the spacing insert 92 and likewise along and around the various components disposed in the potting chamber 160.

Finally, the assembly is mounted in the remainder of the controller can 30.

It is noted that several steps in the above-described process may be implemented in a different order without affecting the final result. Among other things, for instance, the potting shield could be put into place after the fasteners are tightened, or the thermal sheet could be inserted after the thermal insert is placed in the can housing.

It is also noted that the spacing insert 92 in this embodiment does not itself provide primary retentive forces on the power module 60. Rather, the spacing insert 92 provides initial proper positioning of the power module 60 through engagement of the spacing insert body 98 and the positioning elements 120 with the daughter board 62 and engagement of the projections 104 with the power module 60. The spacing insert 92 additionally serves to properly position the nuts 138 and, in turn, to at least in part position and support the fixation elements 94. Final retention of the power module 60 is provided by the clamping forces applied by the clamping surfaces 148 and 150 of the fasteners or fixation elements 94. Thus, any plastic creep or other deformation that might affect the positioning of the insert 92 during motor operation (due to extreme and/or varying temperatures, for instance) does not result in shifting of the power module 60 and any associated detrimental effects, including but not limited to potential loss of or decrease in thermal communication between the power module 60 and the heatsink 52.

### Interchangeability of Power Module and Spacing Insert

The above-described invention provides numerous advantages, including but not limited to the previously discussed positioning of the power module 60 relative to the daughter board 62 by the spacing insert 92; the initial positioning of the nuts 138 by the spacing insert 92; and the overall positioning and mounting to the heatsink 52 of the power module 60 by the clamping assembly 90 (more particularly, the fixation elements 94 thereof). However, it is particularly noted that the inventive design of the motor 10 and, in particular, the clamping assembly 90, additionally facilitates ease in accommodating modification to the power module 60. More particularly, a design change requiring a thicker or thinner power module can be readily supported through provision of an alternative thicker or thinner spacing insert.

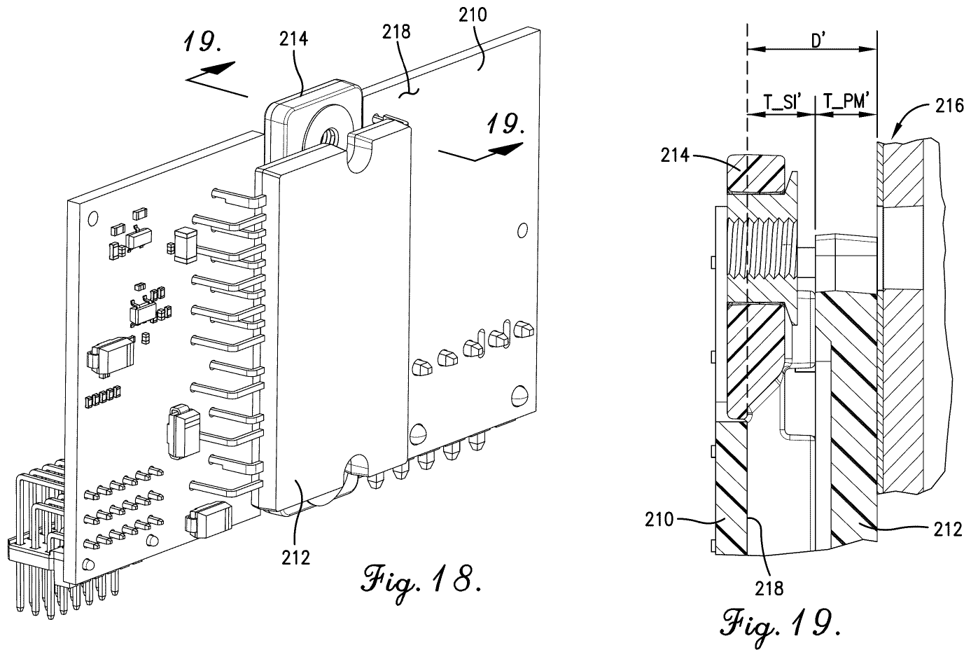

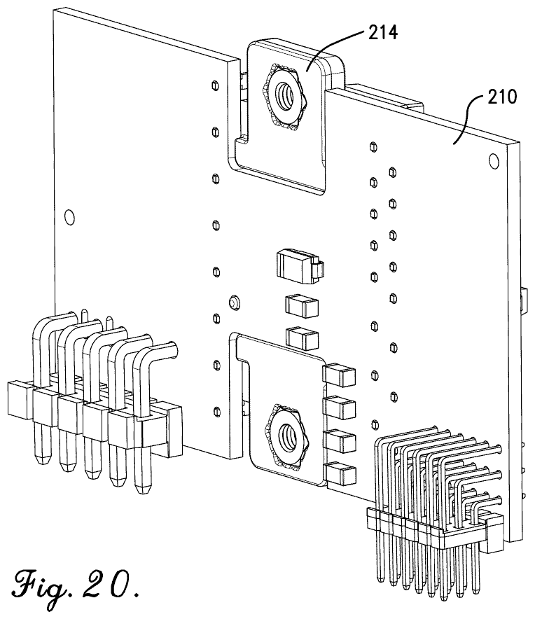

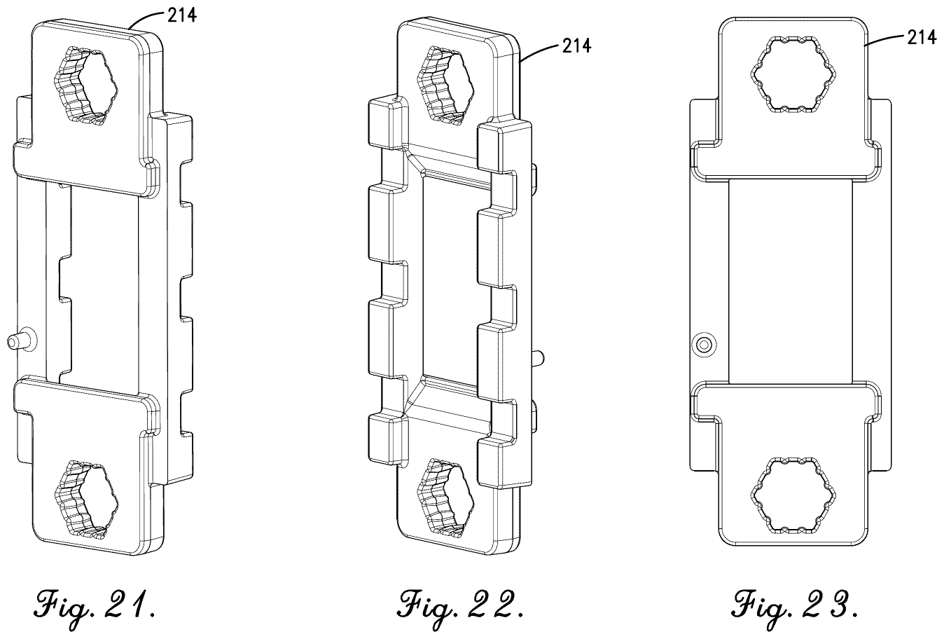

For instance, FIGS. 18-23 illustrate a second embodiment of the present invention in which a thicker power module is provided. It is initially noted that, with certain exceptions to be discussed in detail below, many of the elements of the second embodiment are the same as or very similar to those described in detail above in relation to the first embodiment. Therefore, for the sake of brevity and clarity, redundant descriptions and numbering will be generally avoided here. Unless otherwise specified, the detailed descriptions of the elements presented above with respect to the first embodiment should therefore be understood to apply at least generally to the second embodiment, as well.

With reference to FIG. 13, which illustrates the first preferred embodiment of the present invention, the power module 60 of the first embodiment has a power module thickness T_PM.

The spacing insert 92 has a spacer thickness T_SI, defined by the spacer portion 135 (that is, the body 98 and the projections 104 as disposed between the daughter board 62 and the power module 60). It is noted that the positioning elements 120 in a preferred embodiment may vary in dimension in the thickness direction (that is, from front to back) without having a substantial effect on overall functionality of the spacing insert 92 and are not included in the spacer thickness. Furthermore, the spacer thickness T_SI as defined above is directly relevant to provision and maintenance of the desired spacing between the daughter board 62 and the power module 60.

Finally, an offset O is defined between the board surface 96 and the power module board-facing surface 82. The offset O is equal to the spacer thickness T_SI in a properly configured motor 10, as illustrated.

Similarly, in the properly configured motor 10, the sum of the offset O and the power module thickness T_PM is equal to the sum of the spacer thickness T_SI and the power module thickness T_PM, which is equal to the gap distance D between the board surface 96 and the heatsink 52.

It is noted that, in the illustrated embodiment, the spacer thickness T_SI is constant along the collective span or length of the projections 104. Furthermore, the power module thickness T_PM is constant along its length, and the offset O and gap distance D are unchanging between the spacer 92 and the power module 60. As noted above, the various engaged surfaces are also planar. However, it is permissible according to some aspects of the present invention for thickness variations to occur along the component lengths, for the offset distance to change lengthwise, and/or for the gap distance D to vary along the component lengths. Preferably, however, any such variations are accompanied by complementary variations in relevant components such that the desired contact or spacing between key parts is achieved.

As will be apparent to those of ordinary skill in the art, if the power module had a greater thickness than shown in FIG. 13 and others, the original spacing insert of the first embodiment would position the power module too far toward the heatshield. That is, the assembly as a whole would be too large for its provided envelope within the motor. A configuration change would be required. In the present invention, this dilemma is solved through substitution of the original spacing insert for one having a decreased thickness. That is, the spacing insert may be understood to be interchangeable. Importantly, no modification is required to be made to any of the more complex and expensive components of the motor in order to accommodate the thicker power module.

For instance, FIGS. 18-23 illustrate a daughterboard 210, a power module or heat-generating component 212, a spacing insert 214, and a heatsink 216. As shown in FIG. 19, the gap distance D′ between a heatsink-facing board surface 218 and the heatsink 216 is the same as the gap distance D of the first embodiment. That is, the daughterboard 210 is still mounted to the main PCB (not shown) in the original location, and the heatsink 218 remains unchanged in both its position and configuration. Stated yet another way, the overall or general motor design is unchanged.

However, the power module 212 has a thickness T_PM′ that is greater than the thickness T_PM of the power module 60 of the first embodiment. To accommodate this increase in power module thickness T_PM′, the new spacing insert 214 has a thickness T_SI′ that is smaller than that of the spacing insert 92 of the first embodiment. The sum of the thicknesses T_PM′ and T_SI′ of the thicker power module and thinner spacing insert is equal to the gap distance D′ in the second embodiment, as well as the gap distance D in the first embodiment and, in turn, the sum of the thicknesses T_SI and T_PM of the first embodiment.

In a broad sense, it may be understood that the thickness of a given spacing insert preferably varies inversely and in proportion to the thickness of the corresponding power module, all other components being unchanged. For instance, as the power module thickness increases from T_PM to T_PM′, the spacing insert thickness decreases by an equal amount from T_SI to T_SI′, such that the sum of the thicknesses remains unchanged.

It is again emphasized that, from a design perspective, it is highly advantageous to be able to reconfigure a motor to utilize a differently sized power module without necessitating major design changes to accommodate it. The present design, which requires only a change to a single, easy-to-produce and inexpensive spacing insert, is such an advantageous design and enables the power modules and the spacing inserts to each be treated as interchangeable.

It is also noted that the spacing insert concept of the present invention additionally facilitates ease of accommodation of changes to the shape and/or size of the daughter board. For instance, the sizes and/or shapes of the side sections, bridge, and so on (including the thicknesses thereof) may be easily adjusted to through provision of a modified spacing insert. For instance, reconfigured positioning elements, a modified spacer portion thickness, and so on may be provided.

In view of the above, one may describe a method of maintaining spacing between a daughter board and a selected one of a plurality of potential power modules (that is, interchangeable power modules, such as the power modules 60 and 212)), each having its own thickness, and securing such interchangeable power module in thermal communication with a heatsink (such as the heatsink 52 or 216).

In such a method, a first step includes acquiring an interchangeable spacing insert (such as the spacing insert 92 or 214) having a thickness corresponding to the selected one of the interchangeable power modules (such as the power module 60 or 212). Such interchangeable spacing insert may be selected from a group of pre-formed (existing) inserts having different thicknesses, or the selected interchangeable spacing insert may be formed (molded, printed or additively manufactured, machined, or otherwise created) based on the desired thickness.

It is noted that the term “interchangeable” as used herein means that a selected spacing assembly or power module could be replaced by (that is, interchanged with) a different spacing assembly or power module without substantial tweaking or modification of other components, except for the associated power module or spacing assembly, respectively.

The selected interchangeable spacing insert may then be mounted to the daughter board (such as the board 62 or 210).

The interchangeable power module may be mounted to the daughter board thereafter, such that the selected interchangeable spacing insert is in contact with each of the daughter board and the interchangeable heat-generating component.

As will be readily apparent to those of ordinary skill in the art based on prior discussion, the thickness of the selected one of the interchangeable spacing inserts is preferably such that, upon completion of the mounting of the interchangeable spacing insert to the daughter board and securement of the interchangeable power module to the daughter board, the interchangeable power module is disposed or positioned in thermal communication with the heatsink.

Additional steps in such method would follow those described above in relation to the first embodiment, including the insertion and tightening of fasteners (e.g, the fixation elements or fasteners 94) to initiate and effectuate clamping of the interchangeable power module to the heatsink.

It is noted that other clamping or mounting mechanisms, including bars or other conventional means, may be substituted or additionally utilized in some methods of power module spacing and securement without departing from the scope of some aspects of the present invention. That is, the clamping process that occurs after the spacing insert has properly positioned the power module relative to the daughter board and, in turn, the heatsink may vary from that described above without departing from some aspects of the present invention. Such methods, however, most preferably still retain the steps of the selecting an interchangeable power module and interchangeable spacing insert of complementary thicknesses.

It is also noted that certain steps of the above-described method may be performed in one or more alternate orders. However, it is preferred that the spacing insert be placed in position prior to securement of the power module to the daughter board and prior to clamping of the power module relative to the heatsink.

### Alternative Potting Shield Design for Improved Flow

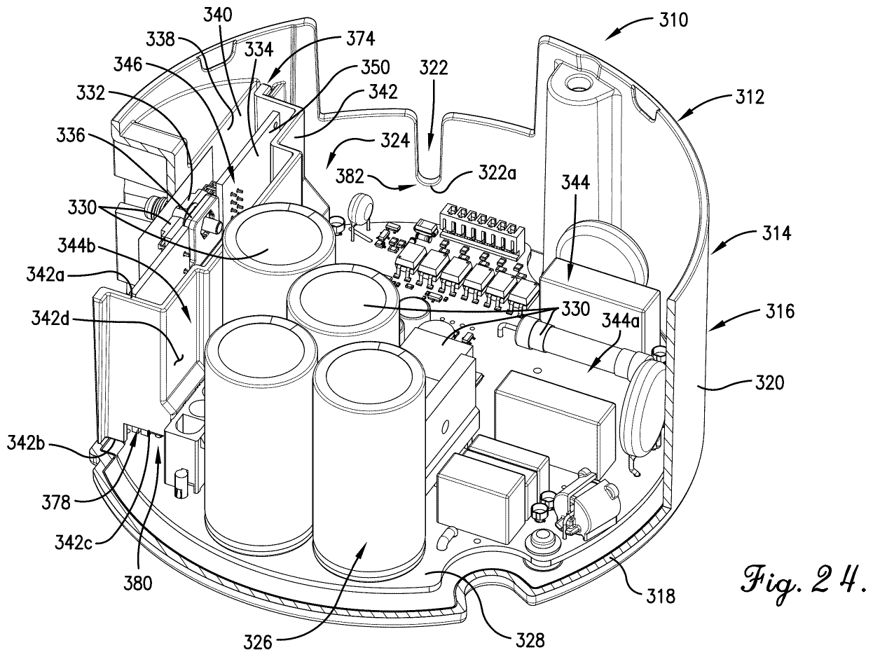

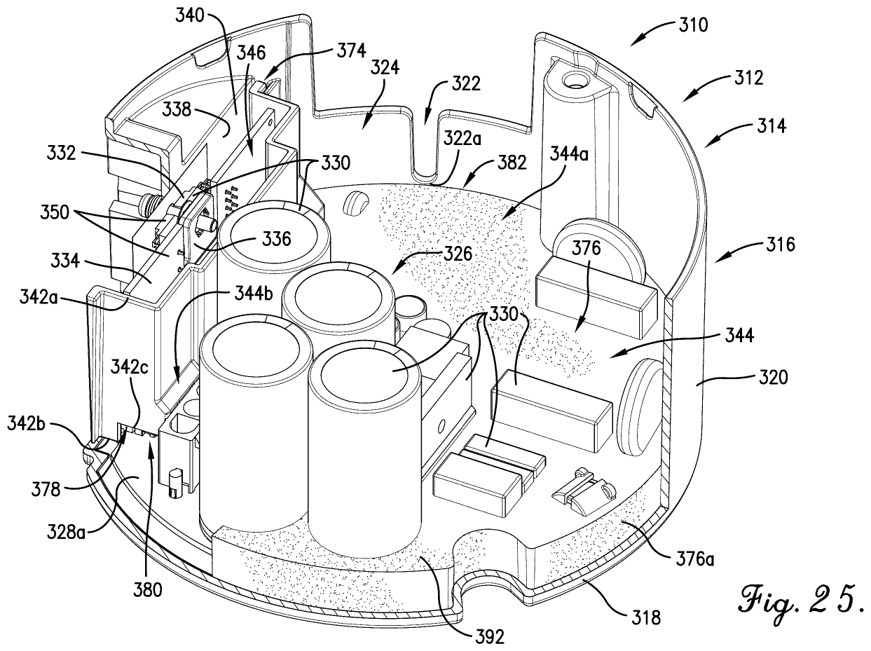

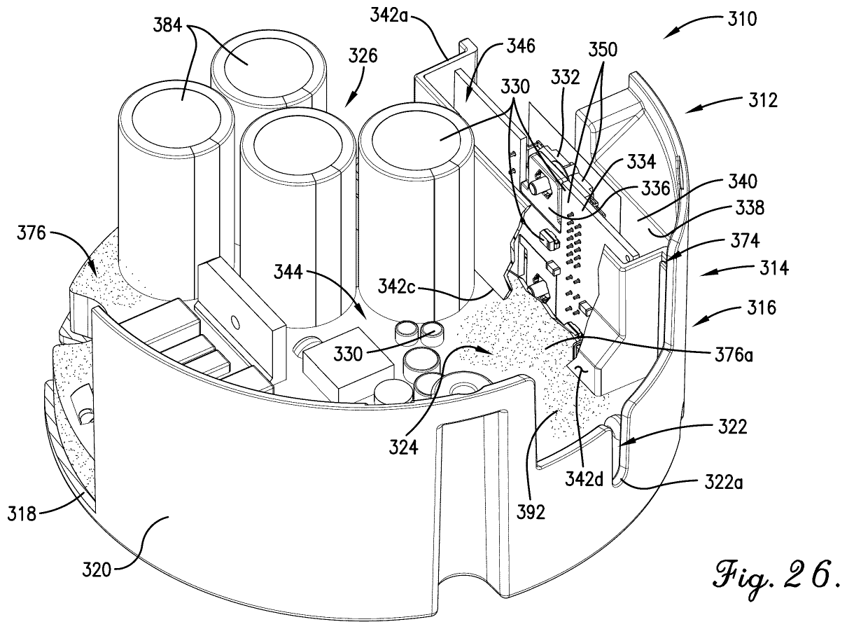

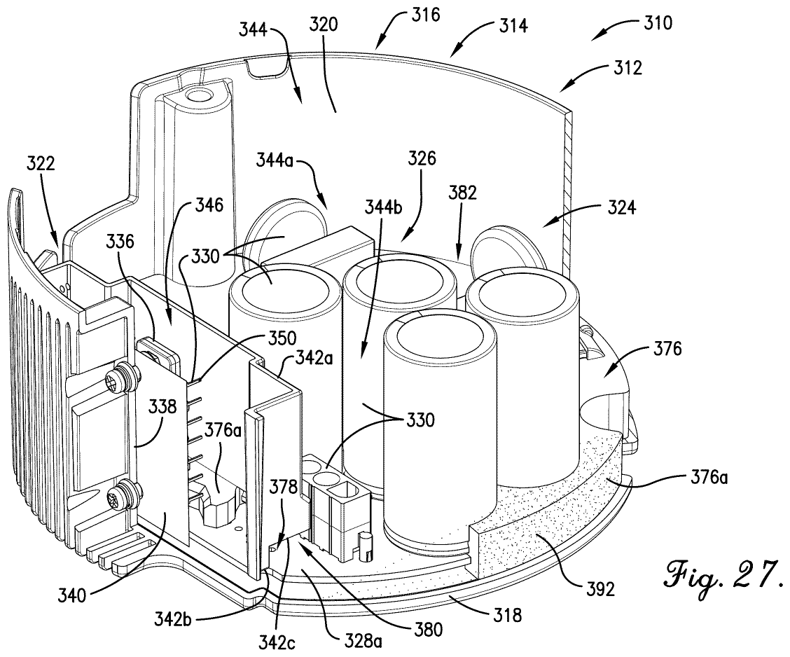

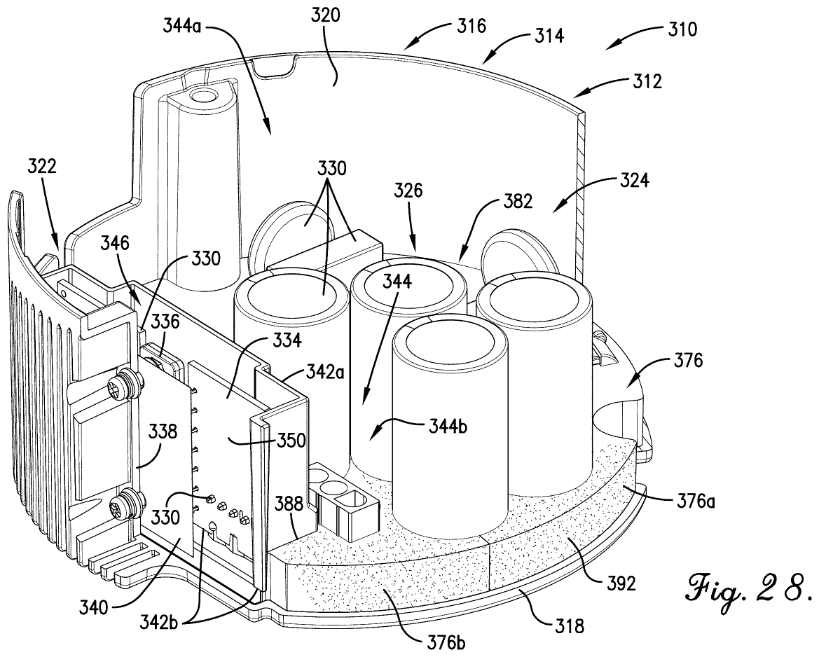

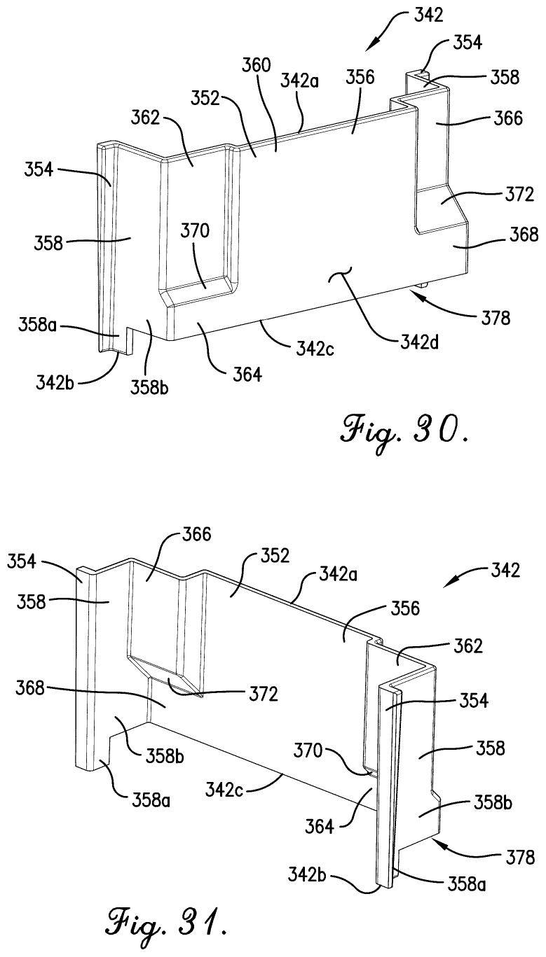

A third preferred embodiment of the present invention is illustrated in FIGS. 24-31. It is initially noted that, with certain exceptions to be discussed in detail below, many of the elements of the motor 310 of the third embodiment are the same as or very similar to those described in detail above in relation to the motor 10 of the first embodiment. Therefore, for the sake of brevity and clarity, redundant descriptions and numbering will be generally avoided here. Unless otherwise specified, the detailed descriptions of the elements presented above with respect to the first and second embodiments should therefore be understood to apply at least generally to the third embodiment, as well.

Similarly to the motor 10 of the first preferred embodiment, the motor 310 of the third preferred embodiment preferably includes a motor housing 312 including a controller can 314. The controller can 314 preferably includes a can housing 316. The can housing 316 includes a generally radially extending end plate 318 and a generally circumferential skirt 320 extending at least substantially axially from the end plate 318. The can housing 316 and an adjacent endshield (not shown, but preferably similar to the endshield 26 of the first embodiment), preferably cooperatively define a controller chamber 324.

In contrast to the skirt 36 of the first preferred embodiment, the skirt 320 of the controller can 314 preferably includes an axially extending overflow opening or slot 322 having an end 322a spaced axially upward from the end plate 218. The function of the slot 322 will be discussed in greater detail below.

The motor 310 preferably includes a controller 326 at least in part and most preferably at least substantially received in the controller chamber 324. The controller 326 preferably includes a main, primary, or parent motor board or electronics board 328 (preferably a printed circuit board or PCB) and a plurality of electronics components 330 mounted on the main electronics board 328.

The main electronics board 328 is preferably generally planar and overlies or nearly overlies the end plate 318 of the can housing 316. Alternatively described, the main electronics board 328 preferably extends parallel to and adjacent the end plate 318. The electronics components 330 extend from the main electronics board 328 into the controller chamber 324.

In a preferred embodiment of the present invention, the electronics components 330 of the controller 326 include a power module 332 and a secondary or daughter electronics board 334, in addition to other components. A clamping assembly 336 preferably secures the power module 332 relative to the daughter electronics board 334 and a heatsink wall 338 defined at least in part by the controller can 314. (The heatsink wall 338 is preferably part of a heatsink 340 similar to the heatsink 52 of the first preferred embodiment.)

The daughter board 334 is preferably mounted at least substantially orthogonally relative to the primary board 328, although non-orthogonal mounting falls within the scope of some aspects of the present invention.

In a preferred embodiment, the controller 326 additionally includes a potting shield 342 that is positioned relative to the daughter board 334, the power module 332, the clamping assembly 336, and the heatsink wall 338.

As will be discussed in greater detail below, the controller chamber 324 preferably includes a main or primary chamber portion 344 and a secondary or daughter chamber portion 346, with the potting shield 342 being disposed therebetween. Alternatively described, the potting shield 342 cooperates with the controller can housing 316 to define the primary and secondary chamber portions 344 and 346.

As will be discussed in greater detail below, the electronics components 330 preferably include a plurality of primary electronics components 348 that are at least substantially located in the primary chamber portion 344, and a plurality of secondary electronics components 350 that are at least substantially located in the secondary chamber portion 346.

Similarly to the potting shield 158 of the first preferred embodiment, the potting shield 342 of the third preferred embodiment preferably includes a main body 352 and a pair of mounting flanges 354. The main body 352 preferably includes a front 356 and a pair of sides 358. The front 356 preferably includes a center section 360, a first upper side section 362, a first lower side section 364, a second upper side section 366, and a second lower side section 368.

The center section 360 is preferably rectangular in form and at least substantially centered relative to the potting shield 342 as a whole. The first and second lower side sections 364 and 368 are preferably formed continuously with and co-planar with the center section 360. In contrast, the first and second upper side sections 362 and 366 are preferably inset relative to the center section 360 and the lower side sections 364 and 368.

First and second slanted transition portions 370 and 372 preferably extend between and interconnect respective first upper and lower side sections 362 and 364 and second upper and lower side sections 366 and 368.

The flanges 354 are preferably received in corresponding slots or grooves 374 defined by the controller can 314.

The configuration of the various sections of the main body 352 and the positioning of the potting shield 342 in general relative to the can 314 is preferably such that the shield 342 is spaced from the daughter board 334, the power module 332, and the clamping assembly 336. Such spacing enables flow of potting material 376 into and through the secondary potting chamber portion 346, as will be discussed in greater detail below.

As noted above, the potting shield 158 of the first preferred embodiment preferably includes flanges 164 received in grooves 184 formed by the controller can 30 such that the interface therebetween is sealed against egress of potting material 108 therepast. Furthermore, the potting shield 158 of the first preferred embodiment preferably includes the bottom edge 158b that engages the main electronics board 42 to also at least substantially restrict egress of potting material 108 therepast. That is, the potting shield 158 of the first preferred embodiment is configured to contain potting material 108 within the potting chamber 160, without egress therefrom, and to also prevent inadvertent ingress of potting material from outside the potting chamber 160.

In contrast, as will be discussed in greater detail below, the potting shield 342 of the third preferred embodiment of the present invention is configured not only to contain a substantial amount of potting material 376 within the secondary potting chamber portion 346, but also to facilitate or direct controlled flow of a portion of the potting material 376 out of the secondary potting chamber portion 346.

More particularly, the potting shield 342 preferably includes a top edge 342a and a bottom edge 342b. The top edge 342a is spaced axially from the main or primary electronics board or circuit board 328. In contrast, the bottom edge 342b engages the primary electronics board 328.

The top edge 342a preferably extends continuously and planarly. In contrast, the potting shield 342 preferably defines a cutout 378 that extends from the bottom edge 342b toward the top edge, such that the bottom edge 342b is discontinuous. That is, the bottom edge 342b includes two (2) laterally spaced apart segments.

In greater detail, in the illustrated embodiment, the flanges 354 and only the terminal or outer portions 358a of the sides 358 (that is, the portions adjacent to the flanges 354) define the bottom edge 342b. The front 356 of the potting shield 342 and inner portions 358b of the sides 358 thereof (that is, the portions adjacent the front 356) extend only partway from the top edge 342a toward the main circuit board 328 to define an intermediate edge 342c. A flow-through gap 380 is defined between such intermediate edge 342c and the main circuit board 328.

Alternatively stated, when the potting shield 342 is mounted to the can 314 and relative to the main circuit board 328, the potting shield 342 and the main electronics board 328 define the flow-through gap 380 therebetween, with the intermediate edge 342c defining an upper margin of the gap 380.

It is noted that, as used herein, the cutout 378 refers to the opening defined in/exclusive by the potting shield 342, whereas the flow-through gap 380 refers to the opening cooperatively formed by the potting shield 342 and the main electronics board 328. (The flow-though gap 380 in the illustrated embodiment thus includes the cutout 378 but is bounded at its lower edge by the main electronics board 328.)

In some embodiments, the flow-through gap may instead be fully defined by the potting shield or, alternatively described, be fully coextensive with a cutout in the shield. For instance, the flow-through gap could be formed though the potting shield and spaced vertically (axially) from the main electronics board. In such an embodiment, the cutout in the potting shield fully defines the flow-though gap.

In a preferred method of motor assembly, the main circuit board 328 and associated primary electronics components 348 are mounted in the controller chamber 324. The daughter board 334, the power module 332, and any other secondary electronics components 350 are then mounted in the controller chamber 324 and connected to the main circuit board 328 as required. More particularly, the daughter board 334 and the power module 332 are secured to the controller can 314 by the clamping assembly 336.

The potting shield 342 is then installed via sliding of the flanges 354 into the corresponding grooves 374 until the bottom edge 342b engages the main electronics board 328. The potting shield 342 thus cooperates with the can 314 to form the primary and secondary potting chamber portions 344 and 346. Alternatively described, the potting shield 342 acts as a divider between the daughter or secondary potting chamber portion 346 and the remainder of the controller chamber 324, including the aforementioned primary potting chamber portion 344, with the flow-through gap 380 interconnecting the primary and secondary chamber portions 344 and 346.

A first quantity 376a of potting material 376 is next injected, poured, or otherwise supplied/introduced into the primary potting chamber portion 344. The first quantity 376a of potting material 376 preferably flows across the main circuit board 328 and around the various primary electronics components 348 mounted thereto.

Provision of the first quantity 376a of potting material 376 is preferably controlled such that the material 376 in the primary chamber portion 344 reaches a primary fill level 373 at or below the lower end 322a of the overflow slot 322. That is, the step of supplying potting material 376 into the primary chamber portion 344 is preferably terminated or deemed complete when the primary fill level 373 has been reached.

In an alternate scenario, an excess amount of the first quantity of potting material 376 may be provided and overflow through the slot, such that the desired primary fill level 373 is nevertheless achieved.

The first quantity 376a potting material 376 preferably encases (alternatively, envelops, covers, encapsulates, and so on) at least a portion of the controller 326, including at least some of the primary electronics components 348 thereof. More particularly, it is noted that portions of the controller 326 (including part of some of the components 330) project above the potting material 376, although the potting material 376 most preferably encases (and seals) certain (or all) electrically conductive elements of the controller 326.

In some circumstances, the first quantity 376a of potting material 376 may fail to flow around certain ones of the electronics components 330 and/or be restricted it its flow. This can result in portions of the primary electronics board 328 being insufficiently covered by potting material or even left entirely exposed even when provision and subsequent flow of the first quantity 376a of potting material 376 is complete.

As shown in FIGS. 25-28, for instance, the primary electronics components 348 include a plurality of obstructive components 384 (in the illustrated embodiment, such components being capacitors 384, although other types of obstructive components may alternatively or additionally be present). Although a main zone 344a of the primary chamber portion 344 is filled with the first quantity 376a of potting material 376, an exposed area 328a of the board 328 remains even after the potting material 376 has reached the primary fill level 373 and cured or partially cured, due to obstruction of potting material flow by the obstructive components 384. Alternatively stated, an unfilled, dead, or obstructed zone 344b remains in the primary chamber portion 344 after completion of the initial potting phases, with the obstructive components 384 generally separating the obstructed zone 344b from the main zone 344a.

As will be discussed in greater detail below, the flow-through gap 380 is disposed adjacent the obstructed zone 344b, and vice versa. Furthermore, the main zone 344a is preferably in part disposed adjacent the flow-through gap 380.

It is noted that the primary fill level 373 is preferably higher than the intermediate edge 342c of the potting shield 342. The first quantity 376a of potting material 376 therefore preferably engages and forms a seal against an outer face 342d of the potting shield 342 at an interface 376.

It is also noted that some of the first quantity 376a of potting material 376 may flow through the flow-through gap 380 and into the secondary chamber portion 346.

As will be readily apparent to those having ordinary skill in the art, the properties of the potting material 376 itself (for instance, its viscosity, setting or curing rate, and so on) affect how the material flows in relation to obstructions and, in turn, in part determines the presence or absence of un-potted, under-potted, or inconsistently potted areas. However, it will be readily apparent to those of ordinary skill in the art that the potting material 376 of the present invention is at least generally flowable upon initial supply into the controller chamber.

In a preferred method, the first quantity 376a of potting material 376 is allowed to at least in part set or cure prior to a second stage of potting, which is described in greater detail below. That is, the first quantity 376a of potting material 376 is allowed to set (that is, to harden or change consistency by curing, cooling, or similar) to at least such extent that it is no longer highly flowable and instead maintains its general form. For instance, the first quantity 376a of potting material 376 at the end of the first stage of potting may be fully hardened or instead have a malleable, dough-like or clay-like consistency.

It is permissible in other methods falling within the scope of some aspects of the present invention, however, for the next stage of potting to proceed immediately after or shortly after supplying of the first quantity 376a of potting material 376 has ended. (Other potential variations in the potting sequence are discussed below, as well.)

Regardless of the selected approach to setting, upon completion of the first potting stage, a second or additional quantity 376b of potting material 376 is preferably introduced into the secondary chamber portion 346. Because the obstructed zone 344b is in communication with the secondary chamber portion 346 through the flow-through gap 380, some of the additional quantity 376b of potting material 376 is directed out of the secondary chamber portion 346 and into the obstructed zone 344b.

In some instances, other portions of the additional quantity 376b of potting material 376 may flow through other parts of the flow-through gap 380 into the primary chamber portion 344 in areas that are not already sealed off by the first quantity 376a of potting material 376. (Of course, if the flow-through gap 380 has been sealed off by the first quantity 376a of potting material 376, this flow will not occur.)

In a preferred method, when the obstructed zone 344b is filled to an intermediate fill level 388 corresponding to the intermediate edge 342c of the potting shield 342, the additional quantity 376b of potting material 376 begins filling the secondary potting chamber portion 346 and continues until a desired final fill level 390 is reached. In the illustrated embodiment, for instance, the additional quantity 376b of potting material 376 fills the secondary chamber portion 346 in its entirety.

It is noted that, in the illustrated embodiment, the primary fill level 373 and the intermediate fill level 388 are at least substantially equal, although disparate fill levels fall within the scope of some aspects of the present invention.

It is also noted that exact sequencing as described above may not occur in all instances, with various factors, including but not limited to the position of the originally supplied first quantity of potting material, the viscosity of the second quantity of potting material 376, the position of various electronics components and other obstructions, and so on affecting the stages of filling. For instance, a side of the secondary potting chamber portion adjacent the main portion might begin filling before the additional quantity of potting material has reached the intermediate fill level in the obstructed area, or vice versa.

As will be readily apparent to those having ordinary skill in the art, the first quantity 376a of potting material 376 preferably forms a first unitary body 392 disposed primarily in the primary chamber portion 344 but potentially extending between and interconnecting the primary and secondary chamber portions 344 and 346 through the flow-through gap 380.

Similarly, the additional quantity 376b of potting material 376 preferably forms an additional unitary body 394 disposed in both the secondary chamber portion 346 and obstructed zone 344b, with the additional unitary body 394 extending between and interconnecting the secondary chamber portion 346 and the obstructed zone 344b through the flow-through gap 380.

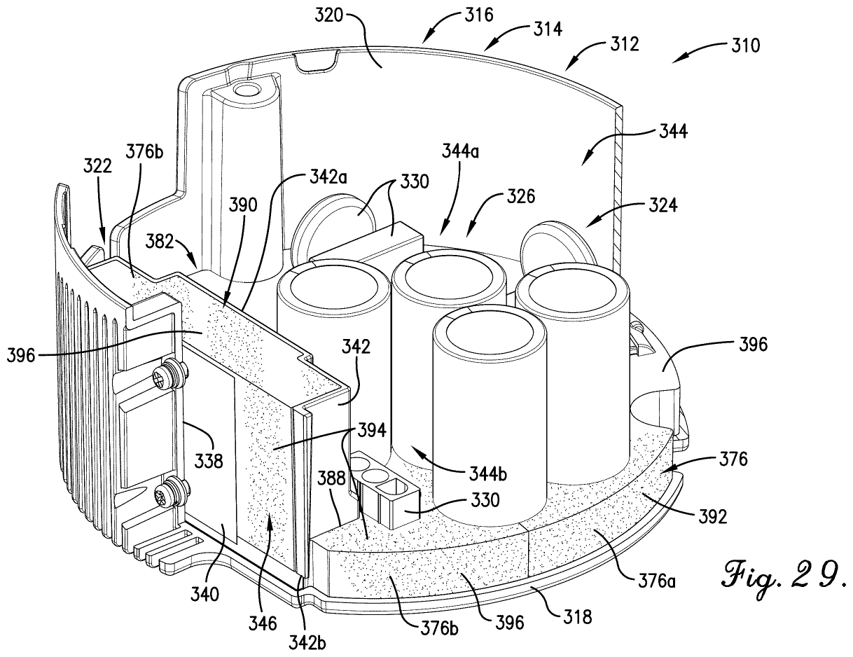

The first and additional unitary bodies 392 and 394 preferably engage one another and potentially even bond to each other (depending on various factors, including but not limited to the properties of the potting material 376, the chosen timing of the potting processes, and so on) to form a complete body 396 (see FIG. 29) of potting material 376.

Although the above-described methodological sequence is preferred, it is also permissible in some inventive methods to first provide potting material into the secondary potting chamber and thereafter provide potting material to the primary potting chamber. Still further, it is permissible according to some aspects of the present invention for potting material to be provided to the chambers entirely simultaneously or partially simultaneously.

As will be apparent from the above, it will therefore be permissible in some instances for the entirety of the potting material to form a single, unitary, generally homogeneous body.

Additional stages of potting material supply may also be added without departing from the scope of some aspects of the present invention.

Furthermore, although the preferred method described above utilizes first and second quantities 376a and 376b of the same potting material 376, varied potting materials may alternatively be used. That is, one composition might be used in one part of the controller chamber, whereas a different composition might be used in another part of the controller chamber.

### CONCLUSION

Features of one or more embodiments described above may be used in various combinations with each other and/or may be used independently of one another. For instance, although a single disclosed embodiment may include a preferred combination of features, it is within the scope of certain aspects of the present invention for the embodiment to include only one (1) or less than all of the disclosed features, unless the specification expressly states otherwise or as might be understood by one of ordinary skill in the art. Therefore, embodiments of the present invention are not necessarily limited to the combination(s) of features described above.

The preferred forms of the invention described above are to be used as illustration only and should not be utilized in a limiting sense in interpreting the scope of the present invention. Obvious modifications to the exemplary embodiments, as hereinabove set forth, could be readily made by those skilled in the art without departing from the spirit of the present invention.

Although the above description presents features of preferred embodiments of the present invention, other preferred embodiments may also be created in keeping with the principles of the invention. Furthermore, as noted previously, these other preferred embodiments may in some instances be realized through a combination of features compatible for use together despite having been presented independently as part of separate embodiments in the above description.

What is claimed is:

1. A motor comprising:
a controller can;
a controller; and
potting material encasing at least a portion of the controller,
said controller including—
a primary electronics board,
a plurality of primary electronics components mounted to the primary electronics board,
a plurality of secondary electronics components, and
a potting shield,
said controller can and said potting shield at least in part defining a controller chamber including a primary chamber portion and a secondary chamber portion,
said primary electronics components being at least substantially located in the primary chamber portion,
said secondary electronics components being at least substantially located in the secondary chamber portion,
said potting shield being disposed between said primary and secondary chamber portions.

2. The motor of claim 1,
said potting shield at least in part defining a flow-through gap interconnecting said primary and secondary chamber portions,
said potting material forming a unitary body extending between and interconnecting the primary and secondary chamber portions through the flow-through gap.

3. The motor of claim 2,
said primary electronics chamber including a main zone and an obstructed zone,
said primary electronics components including an obstructive component at least in part obstructing potting material flow between the main zone and the obstructed zone,
said obstructed zone being disposed adjacent the flow-through gap,
said unitary body of potting material extending between and interconnecting the obstructed zone and the secondary chamber portion through the flow-through gap.

4. The motor of claim 3,
said main zone being in part disposed adjacent the flow-through gap.

5. The motor of claim 3,
said obstructive component comprising a capacitor.

6. The motor of claim 2,
said controller including a secondary electronics board,
said secondary electronics components being mounted to the secondary electronics board.

7. The motor of claim 6,
said secondary electronics board being mounted at least substantially orthogonally relative to the primary electronics board.

8. The motor of claim 2,
said controller can including a generally radially extending end plate and a generally circumferential skirt extending at least substantially axially upwardly from the end plate,
said skirt and said end plate cooperatively in part defining the controller chamber,
said skirt including an overflow opening spaced axially upward from the end plate,
said potting material filling the primary electronics chamber to a primary fill level at or below said opening.

9. The motor of claim 8,
said potting material filling the secondary electronics chamber to a secondary fill level above said primary fill level.

10. The motor of claim 2,
said unitary body being primarily disposed in the secondary chamber portion,
said potting material forming a second unitary body primarily disposed in the primary chamber portion and engaging the first unitary body.

11. The motor of claim 2,
said primary electronics board and said potting shield cooperatively defining the flow-through gap.

12. The motor of claim 11,
said potting shield including a top edge, a bottom edge engaging the primary electronics board, and an intermediate edge disposed between the top and bottom edges and defining an upper margin of the flow-through gap.

13. A method of potting a controller in a motor controller chamber, said controller including a plurality of electronics components, said controller chamber including a primary chamber portion and a secondary chamber portion each at least in part defined by a controller can and a potting shield disposed between the portions, said method including the steps of:
(a) supplying potting material into the primary chamber portion of the controller chamber, such that the potting material at least in part encases a first plurality of said electronics components located in the primary chamber portion;
(b) supplying additional potting material into the secondary chamber portion of the controller chamber, such that the additional potting material at least in part encases a second plurality of electronics components located in the secondary chamber portion; and
(c) after commencement of step (b), directing a portion of said additional potting material to flow from the secondary chamber portion into the primary chamber portion through a flow-through gap at least in part defined by the potting shield.

14. The method of claim 13,
said primary electronics chamber including a main zone and an obstructed zone,
said plurality of electronics components including an obstructive component at least in part obstructing potting material flow between the main zone and the obstructed zone,
step (c) including the step of directing said portion of said additional potting material to flow from the secondary chamber portion through the flow-through gap into the obstructed zone.

15. The method of claim 13,
step (b) commencing after completion of step (a).

16. The method of claim 13, further including the step of:
(d) after commencement of step (a), permitting some of said potting material to flow from the primary chamber portion through the flow-through gap and into the secondary chamber portion.

17. The method of claim 13, further including the step of:
(e) after completion of step (a) and prior to commencement of step (b), permitting said potting material to set.

18. The method of claim 17,
step (c) including the step of directing said portion of the additional potting material to engage said potting material in the primary chamber; and
(f) after completion of steps (b) and (c), permitting said additional potting material to set and to bond to said potting material.

19. The method of claim 13,
step (a) being terminated when the potting material in the primary chamber portion reaches a primary fill level at or below an overflow opening in the controller can.

20. The method of claim 19,
step (b) being terminated when the additional potting material in the secondary electronics chamber reaches a secondary fill level defined above the primary fill level.
